(19) United States
(12) Patent Application Publication
(10) Pub. No.: US 2019/0357385 A1
(43) Pub. Date: Nov. 21, 2019

(54) IMMERSION TANK AND IMMERSION COOLING SYSTEM

(71) Applicant: FUJITSU LIMITED, Kawasaki-shi (JP)

(72) Inventor: Takehide Miyazaki, Yokohama (JP)

(73) Assignee: FUJITSU LIMITED, Kawasaki-shi (JP)

(21) Appl. No.: 16/367,319

(22) Filed: Mar. 28, 2019

(30) Foreign Application Priority Data
May 17, 2018 (JP) 2018-095217

(51) Int. Cl. H05K 7/20; F28F 9/00

(52) U.S. Cl. CPC H05K 7/20236; F28F 2265/10; F28F 9/005

(57) ABSTRACT

An immersion tank includes a tank main body in which refrigerant is stored, and a member that is disposed on the tank main body and retracts, when an electronic apparatus is loaded into the tank main body, to a bottom portion of the tank main body but extends, when the electronic apparatus is unloaded from the tank main body, upwardly from the bottom portion.

### CROSS-REFERENCE TO RELATED APPLICATION

This application is based upon and claims the benefit of priority of the prior Japanese Patent Application No. 2018-95217, filed on May 17, 2018, the entire contents of which are incorporated herein by reference.

### FIELD

The embodiment discussed herein relates to an immersion tank and an immersion cooling system.

### BACKGROUND

There is a technology for cooling an electronic apparatus that generates heat. For example, there are a technology for immersing a semiconductor stack into refrigerant in a sealed container to perform cooling of the semiconductor stack utilizing circulation of the refrigerant with gas-liquid phase change and a technology for providing a sub-chamber that extends or contracts in response to the vapor pressure of gas refrigerant in the sealed container to adjust the liquid level of the liquid refrigerant.

There are a technology for immersing a plurality of electronic parts into refrigerant in a tank and supplying the refrigerant between the electric parts from a plurality of injection ports and a technology for blocking the injection ports in a region in which electronic parts are not disposed such that the refrigerant is not supplied to the region.

There are a technology for using a cooling fan unit to cool a plurality of electronic units mounted at multiple stages in a casing and a technology for providing, in a free space of the casing in which an electronic unit is not mounted, a dummy member that extends and contracts in response to the magnitude of the free space.

In an immersion cooling technology for immersing electronic apparatus into refrigerant in a tank to cool the electronic apparatus, it sometimes becomes a problem that the refrigerant level, temperature distribution and flow velocity distribution in the tank fluctuate depending upon the type, quantity and disposition of the electronic apparatus immersed in the refrigerant in the tank, resulting in failure in sufficient cooling of individual electronic apparatus.

The followings are reference documents.
[Document 1] Japanese Laid-Open Patent Publication No. 61-156755,
[Document 2] Japanese Laid-Open Patent Publication No. 2017-163065 and
[Document 3] Japanese Laid-Open Patent Publication No. 2006-216594.

### SUMMARY

According to an aspect of the embodiment, an immersion tank includes a tank main body in which refrigerant is stored, and a member that is disposed on the tank main body and retracts, when an electronic apparatus is loaded into the tank main body, to a bottom portion of the tank main body but extends, when the electronic apparatus is unloaded from the tank main body, upwardly from the bottom portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are views depicting an example of an immersion cooling system;

FIGS. 2A and 2B are views depicting refrigerant stored in a tank main body of an immersion tank;

FIGS. 3A and 3B are views illustrating flows of refrigerant in a tank main body of an immersion tank and a difference in cooling by flows of refrigerant;

FIG. 4 is a view (part 1) depicting an example of an immersion tank according to a first embodiment;

FIGS. 5A and 5B are views (part 2) depicting an example of an immersion tank according to the first embodiment;

FIG. 6 is a view (part 1) depicting a latch unit of an immersion tank according to the first embodiment;

FIGS. 7A and 7B are views (part 2) depicting a latch unit of an immersion tank according to the first embodiment;

FIG. 8 is a view depicting a stopper of an immersion tank according to the first embodiment;

FIG. 9 is a view depicting an adjustment unit of an immersion tank according to the first embodiment;

FIGS. 10A to 10D are views illustrating loading and unloading of an electronic apparatus into and from an immersion tank according to the first embodiment;

FIGS. 11A and 11B are views illustrating flows of refrigerant in an immersion tank according to the first embodiment;

FIG. 12 is a view illustrating circulation of refrigerant in an immersion tank according to the first embodiment;

FIG. 13 is a view depicting a model of an immersion tank that has been used for thermal fluid analysis;

FIGS. 14A and 14B depict an example of a thermal fluid analysis result of immersion tank in full loading;

FIGS. 15A and 15B depict an example a thermal fluid analysis result of an immersion tank that does not include a bellows tube in a thinned loading state;

FIGS. 16A and 16B depict an example a thermal fluid analysis result of an immersion tank that includes a bellows tube in a thinned loading state;

FIG. 17 is a view depicting a comparison result of electronic apparatus temperatures;

FIG. 18 is a view depicting an example of an immersion cooling system according to the first embodiment;

FIG. 19 is a view (part 1) depicting an example of an immersion tank according to a second embodiment;

FIG. 20 is a view (part 2) depicting an example of an immersion tank according to the second embodiment;

FIG. 21 is a view depicting an example of an immersion tank according to a third embodiment;

FIG. 22 is a view depicting an example of an immersion tank according to a fourth embodiment; and

FIG. 23 is a view depicting an example of an immersion tank according to a fifth embodiment.

### DESCRIPTION OF EMBODIMENTS

First, an immersion cooling technology is described. Immersion cooling is a technology according to which, using fluorinated inert liquid or a like substance having a high heat transport efficiency and an insulating property as refrigerant, into a tank in which such refrigerant is stored, an electronic apparatus that is an object to be cooled such as a server or a storage is immersed such that heat generated from the electronic apparatus when it operates is deprived of by the refrigerant to cool the electronic apparatus. Usually, into a tank in which refrigerant is to be stored, refrigerant of a comparatively low temperature is supplied, and from the tank, the refrigerant of a comparatively high temperature warmed by heat deprived of from the electronic apparatus is discharged to continuously cool the electronic apparatus. An immersion cooling system that adopts such immersion cooling as just described is used for cooling, for example, of an electronic apparatus that has comparatively high heat density and mounting density such as a supercomputer or a high performance computer.

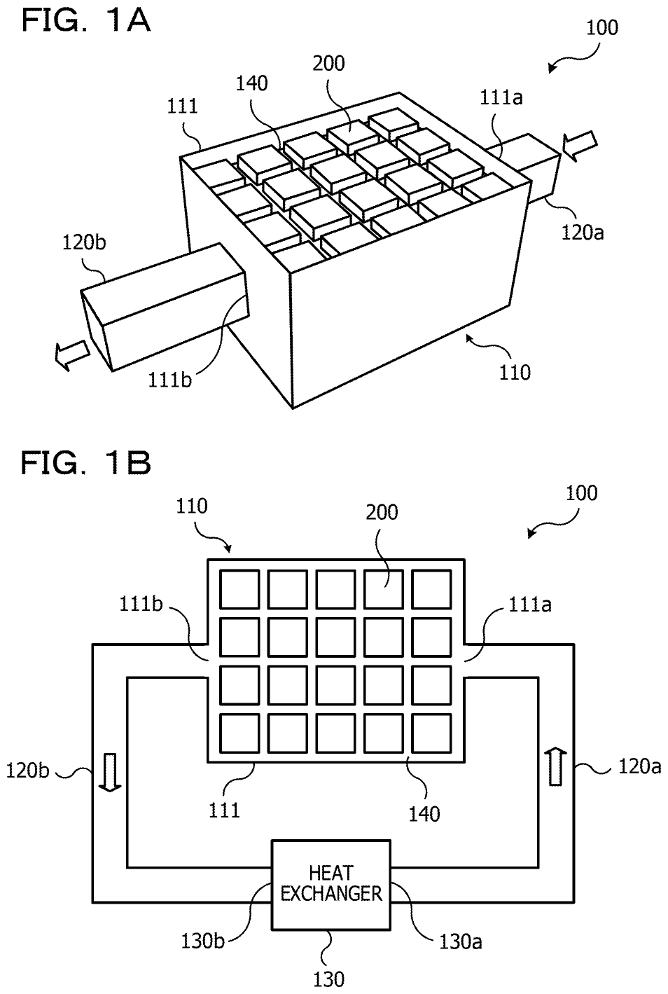

FIGS. 1A and 1B are views depicting an example of an immersion cooling system. FIG. 1A depicts a partial perspective schematic view of an example of an immersion cooling system, and FIG. 1B depicts a block diagram of the example of the immersion cooling system.

The immersion cooling system 100 depicted in FIGS. 1A and 1B includes an immersion tank 110 that performs immersion cooling of electronic apparatus 200 that are objects to be cooled. Refrigerant 140 such as fluorinated inert liquid is stored in a tank main body 111 of the immersion tank 110, and the electronic apparatus 200 are immersed in the refrigerant 140 stored in the tank main body 111. FIGS. 1A and 1B depict, as an example, a state in which the electronic apparatus 200 are loaded (fully loaded) in all of a plurality of places provided for loading of electronic apparatus 200 in the tank main body 111. It is to be noted that the plurality of electronic apparatus 200 that are to be loaded into the tank main body 111 may be of the same type or of different types.

The tank main body 111 of the immersion tank 110 has a supply port 111a and a discharge port 111b for refrigerant 140 provided therein as depicted in FIGS. 1A and 1B. Refrigerant 140 of a comparatively low temperature is supplied (flows) into the tank main body 111 from the supply port 111a, and the refrigerant 140 of a comparatively high temperature in the tank main body 111 warmed by heat deprived of from the electronic apparatus 200 is discharged (flows out) from the discharge port 111b. To the supply port 111a and the discharge port 111b, a duct 120a and another duct 120b are coupled, respectively. As depicted in FIG. 1B, the duct 120a coupled to the supply port 111a is coupled to an exit 130a of a heat exchanger 130 for the refrigerant 140, and the duct 120b coupled to the discharge port 111b is coupled to an entrance 130b of the heat exchanger 130 for the refrigerant 140.

In the immersion cooling system 100, the refrigerant 140 of a comparatively low temperature cooled by the heat exchanger 130 is supplied from the supply port 111a into the tank main body 111 through the duct 120a. The refrigerant 140 supplied from the supply port 111a into the tank main body 111 deprives of heat generated from the electronic apparatus 200 when they operate thereby to cool the electronic apparatus 200. The refrigerant 140 of a comparatively high temperature warmed by heat generated by and deprived of from the electronic apparatus 200 is discharged out of the tank main body 111 from the discharge port 111b and is sent to the heat exchanger 130 through the duct 120b. The refrigerant 140 of a comparatively high temperature sent to the heat exchanger 130 is cooled by the heat exchanger 130. Then, the refrigerant 140 cooled by the heat exchanger 130 is sent back to the tank main body 111 through the duct 120a. In the immersion cooling system 100, the refrigerant 140 is circulated in this manner to perform cooling of the electronic apparatus 200 loaded in the tank main body 111.

The refrigerant 140 stored in the tank main body 111 of the immersion tank 110 in the immersion cooling system 100 having such a configuration as described above is described. In the immersion cooling system 100, the refrigerant 140 of an amount sufficient to fill the ducts 120a and 120b and the heat exchanger 130 and besides cover a given region or an overall region of the electronic apparatus 200 loaded in the tank main body 111 of the immersion tank 110 is used.

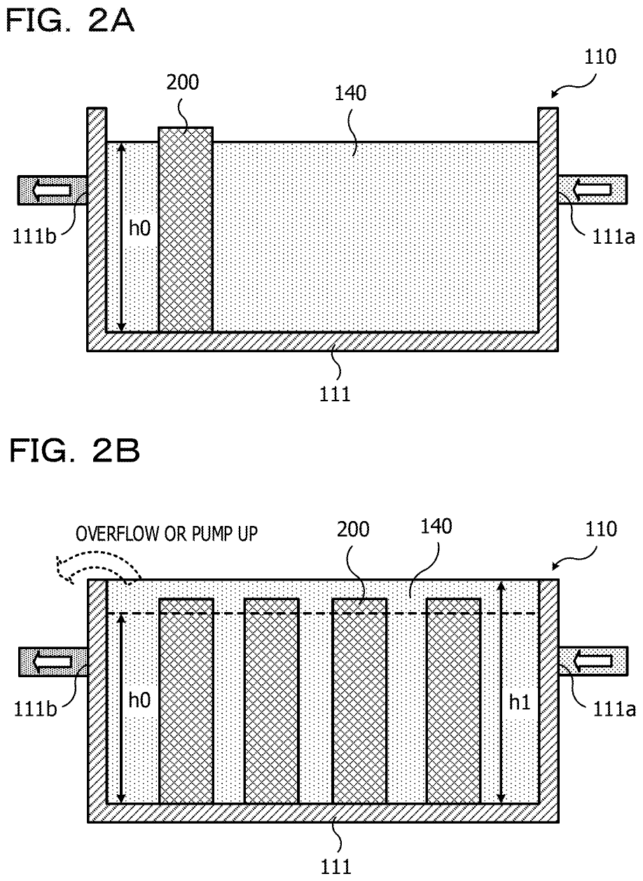

FIGS. 2A and 2B are views depicting refrigerant stored in the tank main body of the immersion tank. FIG. 2A schematically depicts a partial cross section of an example of the immersion tank in which a comparatively small quantity of electronic apparatus are loaded in the tank main body, and FIG. 2B schematically depicts a partial cross section of the example of the immersion tank in which a comparatively great number of electronic apparatus are loaded in the tank main body.

In the tank main body 111 of the immersion tank 110, even if the number of loaded electronic apparatus 200 is small, a quantity (liquid level h0) of refrigerant 140 is stored which may sufficiently cover electronic apparatus 200 (as an example, a given place of the same), for example, as depicted in FIG. 2A.

A case is considered in which, from a state in which a small number of electronic apparatus 200 are loaded in this manner, one or more electronic apparatus 200 are additionally loaded, by expansion or the like, into the tank main body 111 in which the refrigerant 140 of the liquid level h0 is stored. In this case, as depicted in FIG. 2B, the liquid level of the refrigerant 140 stored in the tank main body 111 rises from the liquid level h0 (indicated by a broken line position in FIG. 2B) to another liquid level h1 by an amount corresponding to the additionally loaded electronic apparatus 200. If the amount of the refrigerant 140 including the additionally loaded electronic apparatus 200 exceeds the capacity of the tank main body 111 the refrigerant 140 overflows from the tank main body 111 (indicated by a thick broken line arrow mark in FIG. 2B). Else, it is required to pump up the refrigerant 140 with a pump or the like such that the refrigerant 140 may not overflow from the tank main body 111 (indicated by a thick broken line arrow mark in FIG. 2B).

Conversely, though not depicted here, a case is considered in which a comparatively great number of electronic apparatus 200 are loaded and one or a plurality of ones of the electronic apparatus 200 are unloaded from the tank main body 111 in which the refrigerant 140 is stored with the liquid level h0 sufficient to cover the comparatively great number of electronic apparatus 200. In this case, the liquid level of the refrigerant 140 drops by the unloading of the electronic apparatus 200 from within the tank main body 111, and it possibly occurs that the electronic apparatus 200 remaining in the tank main body 111 may not be covered sufficiently with the refrigerant 140. Else, it is required to additionally supply the refrigerant 140 into the tank main body 111 such that the electronic apparatus 200 remaining in the tank main body 111 are covered sufficiently with the refrigerant 140.

The electronic apparatus 200 loaded into the tank main body 111 of the immersion tank 110 in such an immersion cooling system 100 as described above are described. In the immersion cooling system 100, there is the possibility that various numbers of a variety of types of electronic apparatus 200 may be loaded in various dispositions into the tank main body 111 of the immersion tank 110. The way of flowing, temperature distribution and flow velocity distribution of the refrigerant 140 in the tank main body 111 vary depending upon the combination of a type, a quantity and a disposition of the electronic apparatus 200 to be loaded.

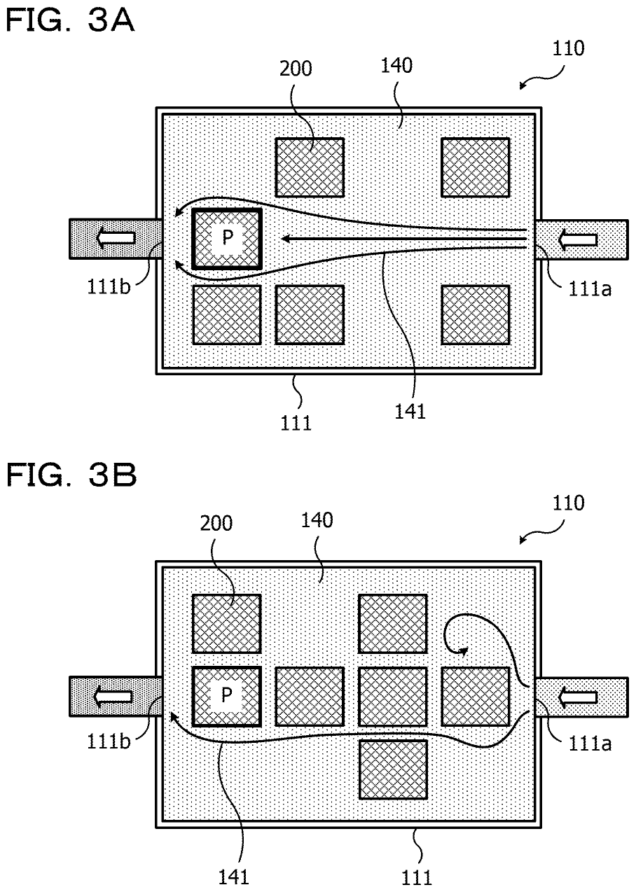

FIGS. 3A and 3B are views depicting flows of refrigerant in a tank main body of an immersion tank and a difference in cooling by flows. FIGS. 3A and 3B schematically depict partial plan views of an example of the immersion tank in which a plurality of electronic apparatus are loaded in dispositions different from each other.

For example, two cases are considered in which, as depicted in FIGS. 3A and 3B, a plurality of electronic apparatus 200 are loaded in the tank main body 111 of the immersion tank 110 not fully but in such a manner that they are loaded at several ones of a plurality of places provided for loading of electronic apparatus 200 (thinned loading). Here, attention is paid, from among the plurality of electronic apparatus 200 loaded in the tank main body 111, an electronic apparatus P loaded at a same place in both of the cases of FIGS. 3A and 3B. The electronic apparatus P is an electronic apparatus 200 positioned on a line interconnecting the supply port 111a and the discharge port 111b of the tank main body 111 as viewed in a top plan view.

In the case depicted in FIG. 3A, no other electronic apparatus 200 is disposed on the line interconnecting the supply port 111a of the tank main body 111 and the electronic apparatus P. Therefore, a flow 141 of refrigerant 140 supplied from the supply port 111a is comparatively likely to hit the electronic apparatus P. On the other hand, in the case depicted in FIG. 3B, a different electronic apparatus 200 is disposed on the line interconnecting the supply port 111a of the tank main body 111 and the electronic apparatus P. Therefore, there is the possibility that a flow 141 of the refrigerant 140 having passed between other electronic apparatus 200 may hit the electronic apparatus P or a flow 141 of the refrigerant 140 of a comparatively high temperature warmed by heat deprived of from other electronic apparatus 200 while the refrigerant 140 passes between the electronic apparatus 200 may hit the electronic apparatus P. It is considered that, in the case depicted in FIG. 3B, the electronic apparatus P is disadvantageous on cooling in comparison with the case depicted in FIG. 3A.

The number of possible combinations of a type, a quantity and a disposition of the electronic apparatus 200 to be loaded in the tank main body 111 of the immersion tank 110 is very great. Therefore, even if the flow rate of the refrigerant 140 to be supplied and discharged is fixed, the way of flowing (flow path), temperature distribution and flow velocity distribution of the refrigerant 140 in the tank main body 111 differ among the different combinations. As a result, it possibly occurs that each individual electronic apparatus 200 is not cooled sufficiently depending upon the position thereof in the tank main body 111 and a surrounding situation (whether or not some other electronic apparatus 200 is or are disposed, and, in the case where some other electronic apparatus 200 is or are disposed, the type and the quantity of them).

In development of electronic apparatus, an operational test in the worst conditions is sometimes carried out. However, as described above, an electronic apparatus 200 that is loaded and cooled in the tank main body 111 is cooled in a way that differs depending upon the position of the electronic apparatus 200 in the tank main body 111 and a surrounding situation. Therefore, with an immersion tank in which the way of flow of the refrigerant 140 in the tank main body 111 differs depending upon the position of each of electronic apparatus 200 in the tank main body 111 and a surrounding situation, a comparatively long period of time is required only to find out the worst condition in regard to each of the electronic apparatus 200.

Taking the foregoing into consideration, such a configuration as described below is adopted for an immersion tank according to embodiments.

### First Embodiment

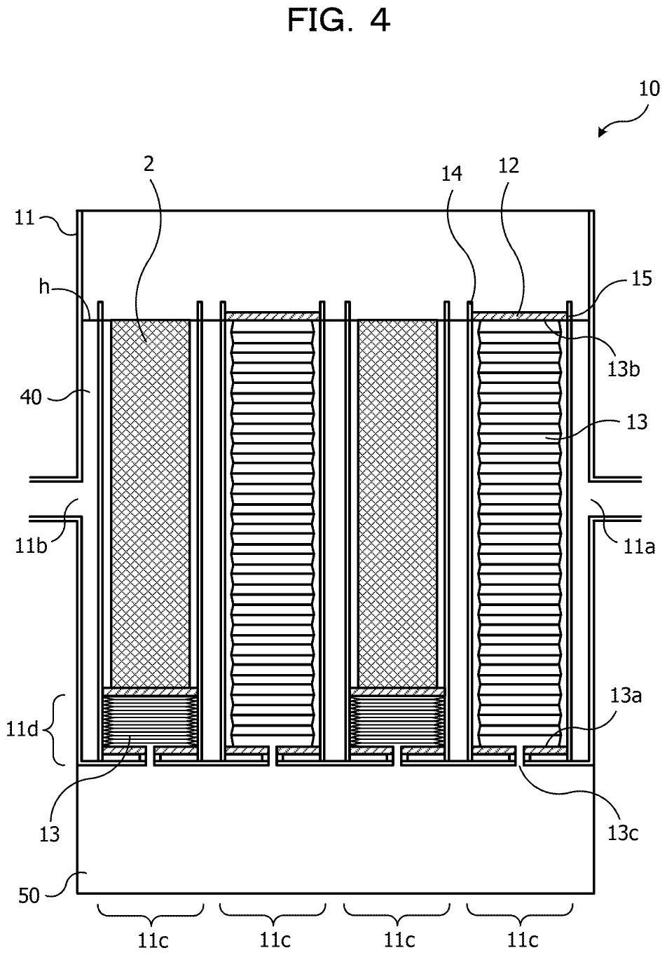

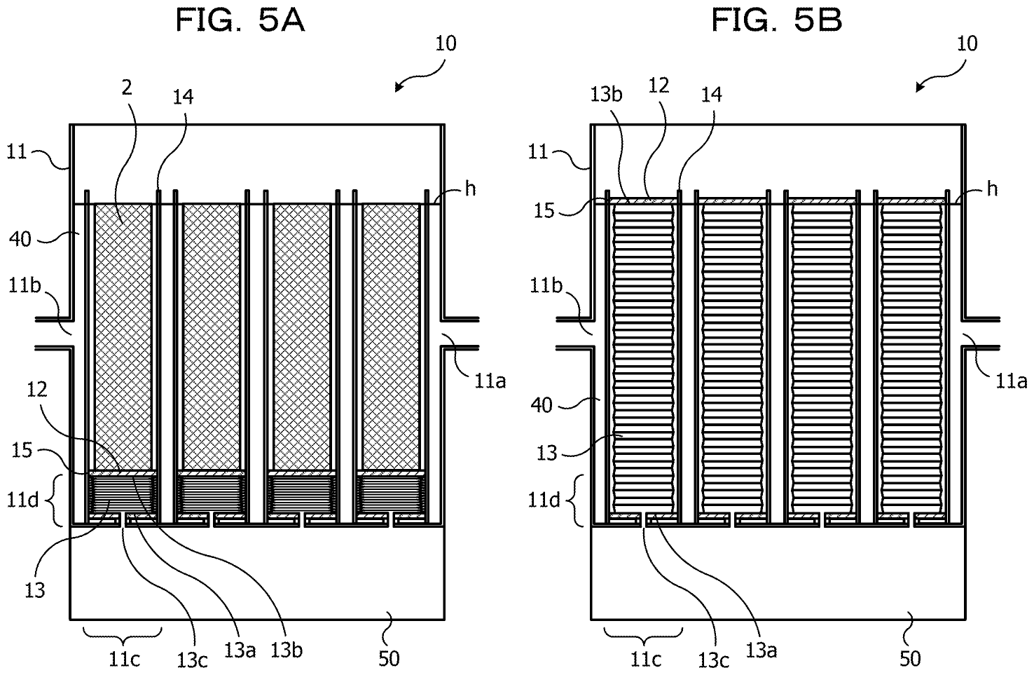

FIGS. 4, 5A and 5B are views depicting an example of an immersion tank according to a first embodiment. FIGS. 4, 5A and 5B schematically depict partial sectional views of an example of the immersion tank.

The immersion tank 10 depicted in FIG. 4 includes a tank main body 11 having a supply port 11a and a discharge port 11b for refrigerant 40 provided therein. In the tank main body 11, an amount of refrigerant 40 sufficient to sufficiently cover a given location or the entirety of electronic apparatus 2 (in the present example, an amount sufficient to cover the electronic apparatus 2 to a height of the upper end of the electronic apparatus 2) is stored.

FIG. 4 illustrates, as an example, a state in which electronic apparatus 2 (two as viewed in a cross sectional view of FIG. 4) are loaded at several ones (two places in the cross sectional view of FIG. 4) from among a plurality of loading places 11c (four in the cross sectional view of FIG. 4) provided for loading electronic apparatus 2 in the tank main body 11.

The quantity of loading places 11c for electronic apparatus 2 and the quantity of electronic apparatus 2 to be loaded in the tank main body 11 are not limited to those in the example depicted in FIG. 4. For example, an electronic apparatus 2 may be loaded in all of the loading places 11c provided on the tank main body 11 as depicted in FIG. 5A. It is to be noted that, before an electronic apparatus 2 is loaded into all of the loading places 11c provided on the tank main body 11 (when no electronic apparatus 2 is loaded), the immersion tank 10 indicates such a state as depicted in FIG. 5B.

At each of the loading places 11c, a stretchable member, for example, such a bellows tube 13 as depicted in FIGS. 4, 5A and 5B, is provided. The bellows tube 13 in each loading place 11c is fixed at a lower end 13a thereof to the bottom of the tank main body 11 and has provided at an upper end 13b thereof a pedestal 12 on which an electronic apparatus 2 is to be loaded.

At each loading place 11c, a guide rail 14 (support post) is provided which stands in the stretching direction of the bellows tube 13 on the outer side of the electronic apparatus 2 loaded at the loading place 11c and the bellows tube 13 provided at the loading place 11c. For example, a plurality of (for example, four: only two are depicted in cross section in FIG. 4) guide rails 14 are provided for each loading place 11c.

The pedestal 12 provided at the upper end 13b of the bellows tube 13 moves up and down under the guidance of the guide rails 14 when the bellows tube 13 extends and contracts in the upward and downward direction. On the pedestal 12 and each guide rail 14, a latch unit 15 (fixing portion) for fixing the pedestal 12 to the guide rail 14 at the raised position is provided.

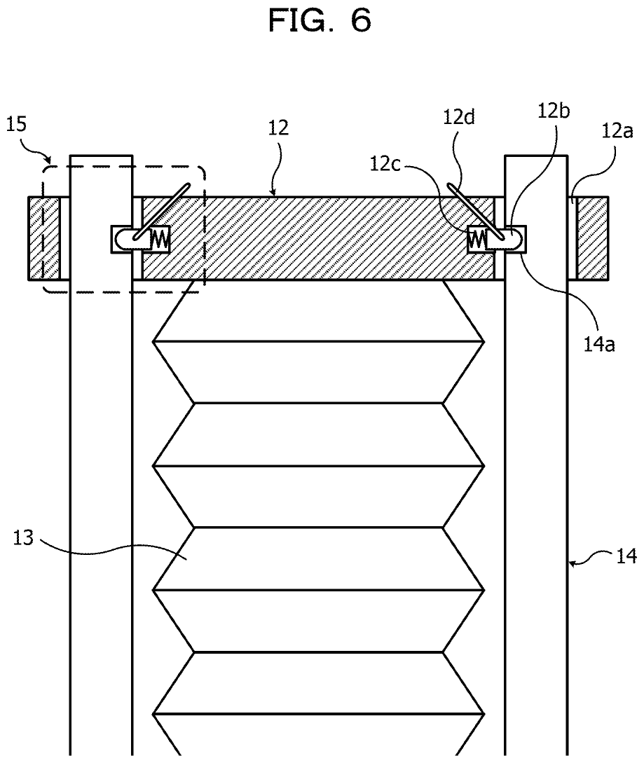

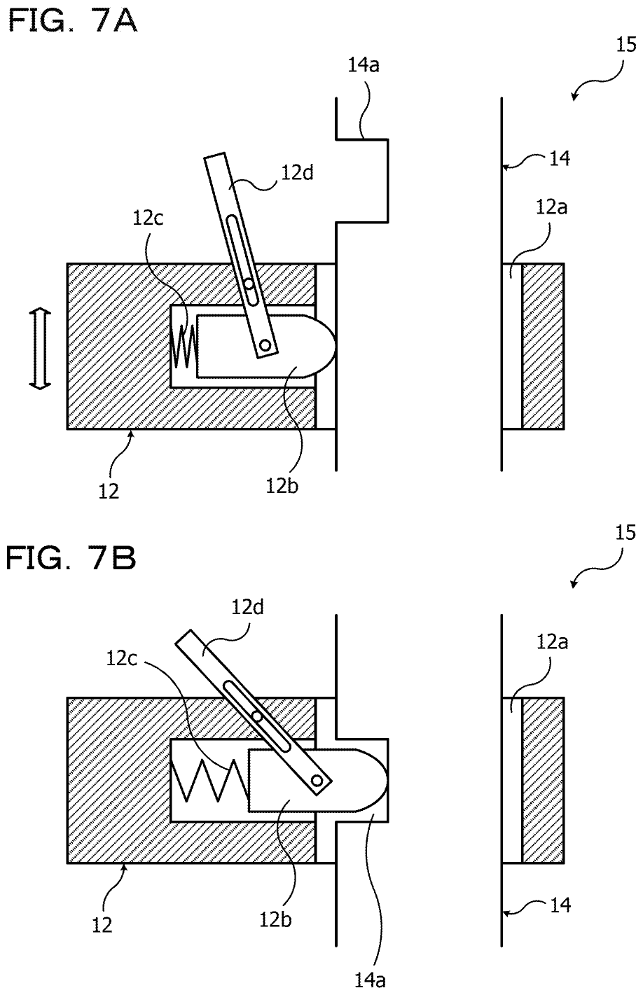

The latch unit 15 is described with reference to FIGS. 6, 7A and 7B. FIGS. 6, 7A and 7B are views depicting a latch unit of an immersion tank according to the first embodiment. FIG. 6 schematically depicts an example of the latch unit. FIG. 7A schematically depicts an example of a state in which fixation by the latch unit is not performed, and FIG. 7B schematically depicts an example of another state in which fixation by the latch portion is performed.

For example, as depicted in FIG. 6, guide holes 12a in which the guide rails 14 are fitted are provided in the pedestal 12. The pedestal 12 moves up and down under the guidance of the guide rails 14 fitted in the guide holes 12a. The pedestal 12 has provided thereon for each of the guide rails 14 a locking member 12b that may project toward the inner side of the corresponding guide hole 12a, a spring 12c that biases the locking member 12b toward the inner side of the guide hole 12a, and a lever 12d for retracting the locking member 12b toward a side wall of the guide hole 12a against the biasing force of the spring 12c. Each guide rail 14 has provided thereon a recessed portion 14a that may accept the corresponding locking member 12b projected to the inner side of the guide hole 12a. The recessed portion 14a is provided, for example, at a height position corresponding to the upper end of the electronic apparatus 2 loaded in the loading place 11c or at a height position corresponding to the set liquid level of the refrigerant 40.

The pedestal 12 moves up under the guidance of the guide rails 14 in such a state that each locking member 12b thereof is pressed against the corresponding guide rail 14 by the biasing force of the spring 12c as depicted in FIG. 7A. If the pedestal 12 moves up until the locking member 12b thereof reaches the recessed portion 14a of the guide rail 14 the locking member 12b is projected into and accepted by the recessed portion 14a by the biasing force of the spring 12c as depicted in FIG. 7B. Consequently, the locking member 12b is locked by the recessed portion 14a and the pedestal 12 is fixed to the guide rail 14 at the raised given height position, for example, at the height position of the recessed portion 14a.

When the pedestal 12 is to be moved down from such a state that the pedestal 12 is fixed to the guide rail 14 as depicted in FIG. 7B, the locking member 12b is retracted from within the recessed portion 14a by the lever 12d. Consequently, the locking of the locking member 12b by the recessed portion 14a is cancelled. The pedestal 12 released from the locking by the locking member 12b thereof is moved down under the guidance of the guide rail 14 in such a state that the locking member 12b is pressed against the guide rail 14 by the biasing force of the spring 12c as depicted in FIG. 7A.

It is to be noted that each guide rail 14 may have provided thereon a recessed portion by which the pedestal 12 is fixed at the moved down position similarly to the recessed portion 14a. In this case, the pedestal 12 is locked by the locking member 12b thereof at a point of time at which the locking member 12b arrives at the recessed portion to fix the pedestal 12 at the lowered position to the guide rail 14, but when the pedestal 12 is to be moved up, the locking of the locking member 12b is cancelled by the lever 12d similarly as in the case of the recessed portion 14a.

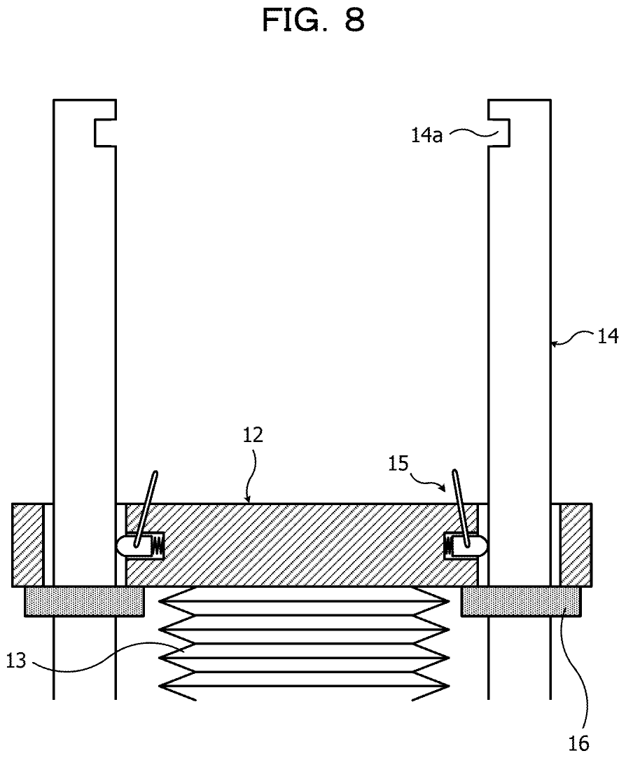

The guide rail 14 may have provided thereof such a stopper as depicted in FIG. 8 in order to fix the pedestal 12 at its lowered position. FIG. 8 is a view depicting the stopper in an immersion tank according to the first embodiment. FIG. 8 schematically depicts an example of the stopper.

For example, the guide rail 14 may have provided thereon such a stopper 16 (fixing member) as depicted in FIG. 8. The stopper 16 may be provided by attaching, to the guide rail 14, a member prepared as a separate part, or may be provided by forming a portion serving as the stopper 16 on the guide rail 14 in advance.

If the guide rail 14 moves down under the guidance of the guide rail 14 until it reaches the stopper 16 further downward movement of the pedestal 12 is restricted and the downward movement of the pedestal 12 is stopped. It is to be noted that, though not depicted, an electronic apparatus 2 may be loaded on the pedestal 12 that moves downwardly. The stopper 16 is provided on the guide rail 14 such that it may support also the weight of the electronic apparatus 2 that may be loaded on the pedestal 12.

The immersion tank 10 is further described with reference to FIGS. 4, 5A and 5B again. In the immersion tank 10, at each loading place 11c at which an electronic apparatus 2 is loaded, the pedestal 12 moves down under the guidance of the guide rails 14 by an amount corresponding to the height of the electronic apparatus 2 placed on the pedestal 12. At the loading place 11c at which the electronic apparatus 2 is loaded, by such downward movement of the pedestal 12, the bellows tube 13 is contracted downwardly of the tank main body 11 in a state in which it is retracted to a bottom portion lid of the loading place 11c.

On the other hand, at a loading place 11c at which an electronic apparatus 2 is not loaded, the pedestal 12 at the own loading place 11c moves up under the guidance of the guide rails 14 to a position corresponding to the upper end of an electronic apparatus 2 placed on a different pedestal 12 as depicted in FIG. 4 (and FIG. 5B). The pedestal 12 is fixed at the moved up position by the latch unit 15. At the loading place 11c at which the electronic apparatus 2 is not loaded, by such upward movement of the pedestal 12, the bellows tube 13 is placed into a state in which it is extended (or expanded) upwardly of the tank main body 11.

The extension and contraction of the bellows tube 13 are performed, for example, by adjusting the internal pressure of the bellows tube 13. In this case, the immersion tank 10 includes, under (the bottom portion lid of) the tank main body 11, an adjustment unit 50 for adjusting the internal pressure of the bellows tube 13 as depicted in FIGS. 4, 5A and 5B.

The adjustment unit 50 introduces given gas, for example, air, from the vent 13c provided at the lower end 13a thereof to increase the internal pressure of the bellows tube 13 thereby to extend the bellows tube 13 upwardly. The adjustment unit 50 discharges the air in the bellows tube 13 from a vent 13c to decrease the internal pressure of the bellows tube 13 thereby to contract the bellows tube 13 downwardly. The adjustment unit 50 may perform such introduction and discharge of air, for example, independently for each bellows tube 13.

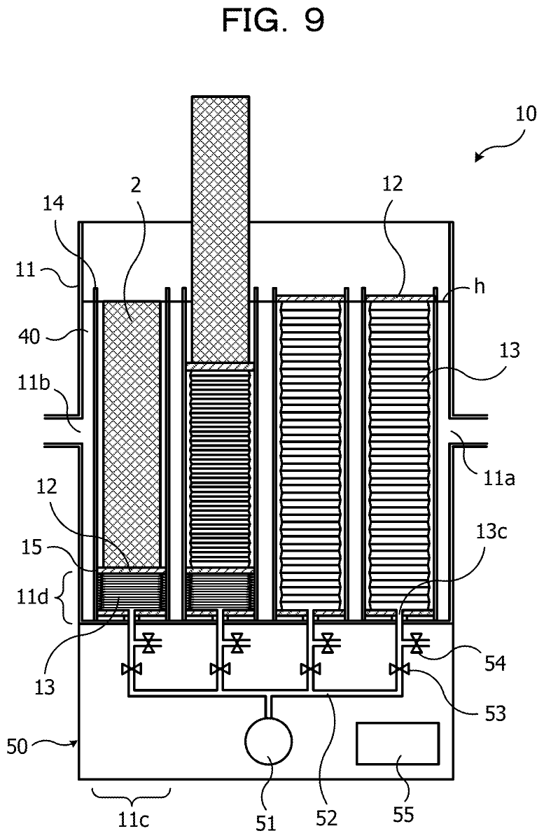

An example of a configuration of the adjustment unit 50 is described with reference to FIG. 9. FIG. 9 is a view depicting the adjustment unit of an immersion tank according to the first embodiment. The adjustment unit 50 includes, for example, as depicted in FIG. 9, a compressor 51, a pipe 52 communicating with the vent 13c of the bellows tube 13 of each loading place 11c, and an introduction valve 53 and a discharge valve 54 provided in the pipe 52. For example, operation of the compressor 51 and the introduction valve 53 and discharge valve 54 is controlled by a controller 55. It is to be noted that the controller 55 may be implemented using a computer.

For example, if air is fed from the compressor 51 into the pipe 52 and is introduced into the bellows tube 13, in which the introduction valve 53 is in an open state and the discharge valve 54 is in a closed state, through the vent 13c the bellows tube 13 is expanded together with increase of the internal pressure and extended upwardly. On the other hand, for example, if air is discharged from within the bellows tube 13, in which the introduction valve 53 is in a closed state and the discharge valve 54 is in an open state, through the vent 13c the bellows tube 13 is contracted together with decreases of the internal pressure.

For example, for each bellows tube 13, the open/closed state of the introduction valve 53 communicating with the vent 13c, the open/closed state of the discharge valve 54, the opening of the introduction valve 53 and the opening of the discharge valve 54 are controlled by the controller 55. This adjusts the internal pressure of the bellows tubes 13, or for example, adjusts extension and contraction (amount, speed and so forth) of the bellows tubes 13.

It is to be noted that the upward extension of each bellows tube 13 may be performed in a state in which an electronic apparatus 2 is not placed on the pedestal 12 or may be performed by increase of the internal pressure of the bellows tubes 13 against the own weight of the electronic apparatus 2 placed on the pedestal 12. The downward contraction of each bellows tube 13 may be performed by the own weight of the electronic apparatus 2 placed on the pedestal 12 or may be performed by the own weight of the electronic apparatus 2 placed on the pedestal 12 and decrease of the internal pressure of the bellows tube 13.

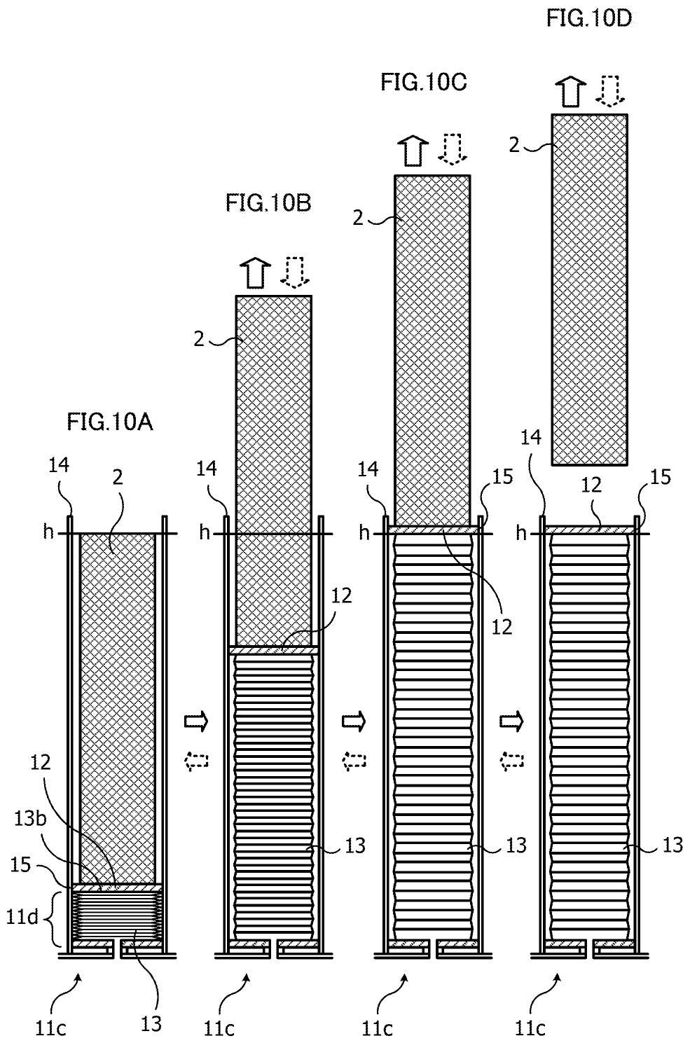

Loading and unloading of an electronic apparatus 2 into and from the immersion tank 10 are described. FIGS. 10A to 10D are views illustrating loading and unloading of an electronic apparatus into and from an immersion tank according to the first embodiment. FIGS. 10A to 10D schematically depict partial cross sectional views of a loading place into and from which an electronic apparatus is loaded and unloaded in a chronological order. It is to be noted that, in FIGS. 10A to 10D, a thick solid line arrow mark represents a flow of unloading of an electronic apparatus and a thick broken line represents a flow of loading of an electronic apparatus.

First, unloading of an electronic apparatus 2 (flow of a thick solid line arrow mark) is described. FIG. 10A depicts an example of a state in which an electronic apparatus 2 is loaded at a loading place 11c provided in the tank main body 11 of the immersion tank 10. Here, the upper end position of the electronic apparatus 2 loaded at the loading place 11c in this manner is a liquid level height h of the refrigerant 40. The bellows tube 13 at the loading place 11c at which the electronic apparatus 2 is loaded is pushed and contracted downwardly by the pedestal 12 on which the electronic apparatus 2 is placed until it is retracted to the bottom portion 11d of the tank main body 11.

From such a state as depicted in FIG. 10A, for example, air is introduced into the bellows tube 13 by such an adjustment unit 50 as described above to increase the internal pressure of the bellows tube 13. The bellows tube 13 is expanded to extend upwardly by the increase of the internal pressure as depicted in FIG. 10B. Together with the upward extension of the bellows tube 13, the pedestal 12 at the upper end 13b of the bellows tube 13 is raised under the guidance of the guide rails 14 to lift the electronic apparatus 2 placed on the pedestal 12 upwardly.

If the bellows tube 13 is extended upwardly by the increase of the internal pressure until the spring 12c comes to a given height, for example, to the upper end position of the electronic apparatus 2 placed on the pedestal 12 (FIG. 10A) or to the liquid level height h of the refrigerant 40 ad depicted in FIG. 10D the pedestal 12 is fixed at the position to the guide rails 14 by the latch units 15. When the pedestal 12 is fixed, the upward extension of the bellows tube 13 is stopped. For example, the introduction valve 53 of the pipe 52 communicating with the vent 13c of the bellows tube 13 is closed or the introduction of air into the bellows tube 13 is continued such that the bellows tube 13 is not contracted downwardly such that increase of the internal pressure of the bellows tube 13 is stopped. Consequently, the upward extension of the bellows tube 13 is stopped.

It is to be noted that, at the time of the upward extension of the bellows tube 13 (FIGS. 10B and 10C), lifting of the electronic apparatus 2 may be assisted manually or by a crane or the like. After the upward extension of the bellows tube 13 (lift of the bellows tube 13) is stopped, the electronic apparatus 2 on the pedestal 12 is unloaded from the immersion tank 10 as depicted in FIG. 10D. The unloading of the electronic apparatus 2 is performed manually or by a crane or the like.

In the unloading of the electronic apparatus 2 performed in such a flow as described above, as the electronic apparatus 2 is lifted, the bellows tube 13 is expanded to extend upwardly (FIGS. 10B and 10C). In the immersion tank 10, the upwardly extended bellows tube 13 comes into existence at the loading place 11c after the unloading of the electronic apparatus 2 in place of the unloaded electronic apparatus 2 (FIG. 10D). In this manner, the bellows tube 13 plays a role as a volume article that exists in the refrigerant 40 in place of the electronic apparatus 2 unloaded from within the refrigerant 40 stored in the tank main body 11 and corresponds to the electronic apparatus 2. Since, in the immersion tank 10, the bellows tube 13 as a volume article corresponding to the unloaded electronic apparatus 2 exists in the refrigerant 40, variation of the liquid level height h (liquid level) of the refrigerant 40 caused by the unloading of the electronic apparatus 2 is suppressed.

Loading of an electronic apparatus 2 (flow of a thick broken line arrow mark) is described. Loading of an electronic apparatus 2 into the immersion tank 10 is performed in a flow reverse to that upon unloading described above. For example, an electronic apparatus 2 transported to such a loading place 11c as depicted in FIG. 10D is placed on the pedestal 12 at the upper end 13b of the bellows tube 13 extending to the liquid level height h of the refrigerant 40 as depicted in FIG. 10C.

After the electronic apparatus 2 is placed on the pedestal 12, fixation by the latch units 15 is cancelled and air in each bellows tube 13 is discharged, whereupon the pedestal 12 moves down under the guidance of the guide rails 14 as depicted in FIG. 10B. For example, the discharge valve 54 of the pipe 52 communicating with the vent 13c of the bellows tube 13 is opened or is opened with the opening thereof adjusted, whereupon the pedestal 12 is pushed by the own weight of the electronic apparatus 2 and air is discharged from within the bellows tube 13. Consequently, the bellows tube 13 contracts downwardly and the pedestal 12 moves down.

When the bellows tube 13 contracts downwardly until the upper end of the pedestal 12 or the upper end of the electronic apparatus 2 comes to a given height, for example, as depicted in FIG. 10A, to a position at which the upper end position of the electronic apparatus 2 placed on the pedestal 12 is in level with the liquid level height h of the refrigerant 40, the contraction of the bellows tube 13 is stopped. For example, by fixation of the pedestal 12 by the latch units 15 or by restriction to the downward movement of the pedestal 12 by the stoppers 16 not depicted, the contraction of the bellows tube 13 is stopped. The bellows tube 13 is retracted to the bottom portion lid of the tank main body 11 by the retraction and the electronic apparatus 2 is loaded at the loading place 11c.

In loading of the electronic apparatus 2 performed in order in accordance with such a flow as described above, as the electronic apparatus 2 moves down, the bellows tube 13 is contracted downwardly (FIGS. 10C and 10B). The bellows tube 13 that has existed in the refrigerant 40 in place of the electronic apparatus 2 (FIG. 10D) is retracted to the bottom portion 11d of the tank main body 11, and the electronic apparatus 2 exists in the tank main body 11 in place of the bellows tube 13 (FIG. 10A). Since, by the loading of the electronic apparatus 2, the bellows tube 13 having existed in the refrigerant 40 as a volume article corresponding to the electronic apparatus 2 is contracted and is retracted to the bottom portion lid of the tank main body 11 in this manner, variation of the liquid level height h of the refrigerant 40 upon loading of the electronic apparatus 2 may be suppressed.

As described above, in the immersion tank 10, the bellows tube 13 is provided which contracts, if an electronic apparatus 2 is loaded into the tank main body 11 in which the refrigerant 40 is stored, downwardly and is retracted to the bottom portion 11d, but is extended, if the electronic apparatus 2 is unloaded, upwardly such that it exists as a volume article corresponding to the electronic apparatus 2 in the refrigerant 40. Since such a bellows tube 13 as just described is provided in the immersion tank 10, both of variation of the liquid level of the refrigerant 40 upon loading of an electronic apparatus 2 and variation of the liquid level of the refrigerant 40 upon unloading of the electronic apparatus 2 may be suppressed. For example, in the immersion tank 10, irrespective of whether or not an electronic apparatus 2 is loaded in the tank main body 11, it is possible to fix the liquid level of the refrigerant 40 stored in the tank main body 11 or to keep the liquid level within a fixed range.

In the immersion tank 10, when an electronic apparatus 2 is newly loaded into the tank main body 11, it is possible to suppress a rise of the liquid level of the refrigerant 40 and keep both of the electronic apparatus 2 loaded newly and any electronic apparatus 2 loaded originally in a state in which they are sufficiently covered with the refrigerant 40. Since the electronic apparatus 2 in the tank main body 11 are sufficiently covered with the refrigerant 40 and besides a rise of the liquid level of the refrigerant 40 is suppressed, it is possible to implement sufficient cooling of the electronic apparatus 2 with the refrigerant 40 and suppress overflow of the refrigerant 40 by the rise of the liquid level, pumping up of the refrigerant 40 and so forth.

In the immersion tank 10, when an electronic apparatus 2 is unloaded from within the tank main body 11, it is possible to suppress drop of the liquid level of the refrigerant 40 and place and keep any electronic apparatus 2 remaining in the tank main body 11 in a state in which it is sufficiently covered with the refrigerant 40. Consequently, it is possible to implement sufficient cooling of the electronic apparatus 2 remaining in the tank main body 11 with the refrigerant 40 and suppress addition of refrigerant 40 for suppressing decrease of the liquid level.

In the immersion tank 10, it is sufficient if a minimum amount of refrigerant 40 is stored in the tank main body 11 when an electronic apparatus 2 is loaded into all of the loading places 11c of the tank main body 11 (or when the bellows tube 13 at all loading places 11c is in a state in which it is extended). Since such overflowing and pumping up as described above may be suppressed and besides the amount of refrigerant 40 to be used may be minimized, reduction of the cost for cooling the electronic apparatus 2 may be anticipated.

Since the immersion tank 10 includes the bellows tube 13 that contracts downwardly and is retracted to the bottom portion 11d of the tank main body 11 when an electronic apparatus 2 is loaded and is extended upwardly when the electronic apparatus 2 is unloaded as described above, fluctuation of a flow of the refrigerant 40 stored in the tank main body 11 may be suppressed. For example, in the immersion tank 10, irrespective of whether an electronic apparatus 2 is loaded or is not loaded in the tank main body 11, the flow of the refrigerant 40 stored in the tank main body 11 may be kept in a similar situation or may be kept in a situation that may be regarded as a similar situation.

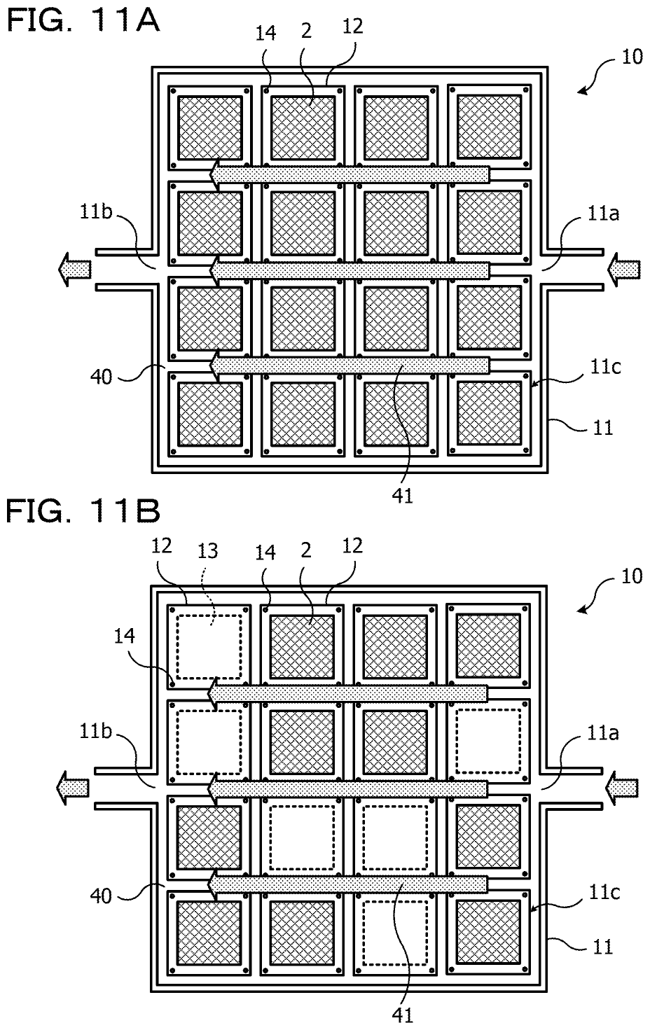

FIGS. 11A and 11B are views illustrating flows of refrigerant in an immersion tank according to the first embodiment. FIG. 11A schematically depicts a partial plan view of an example of the immersion tank in which electronic apparatus are loaded fully, and FIG. 11B schematically depicts a partial plan view of the example of the immersion tank in which electronic apparatus are thinning loaded. It is to be noted that FIGS. 11A and 11B correspond to cross sectional views when the tank main body of the immersion tank are cut in a planar direction at an intermediate height position between the supply port and the discharge port for the refrigerant.

FIG. 11A depicts an example of the immersion tank 10 in which electronic apparatus 2 are fully loaded at all of the loading places 11c (in the present example, at 16 loading places 11c) in the tank main body 11. At each loading place 11c, an electronic apparatus 2 is placed on the pedestal 12 of the bellows tube 13 that is in a downwardly contracted state under the tank main body 11 and retracted to the bottom portion 11d of the tank main body 11 as described hereinabove with reference to FIG. 10A.

FIG. 11B depicts an example of the immersion tank 10 in which electronic apparatus 2 are thinned and loaded at several loading places from among all loading places 11c in the tank main body 11. At each loading place 11c at which an electronic apparatus 2 is loaded, the electronic apparatus 2 is placed on the pedestal 12 of the bellows tube 13 that is contracted under the tank main body 11 and retracted to the bottom portion 11d of the tank main body 11 as depicted in FIG. 10A. At each loading place 11c at which an electronic apparatus 2 is not loaded, the pedestal 12 of the bellows tube 13 extended upwardly of the tank main body 11 is in a state lifted to a height corresponding to the upper end position of the electronic apparatus 2 at the loading place 11c at which the electronic apparatus 2 is loaded as depicted in FIG. 10D.

In such thinned loading as depicted in FIG. 11B, since the bellows tube 13 exists in an upwardly extended state at each loading place 11c at which an electronic apparatus 2 is not loaded, flows 41 of the refrigerant 40 in the tank main body 11 may be made similar to those when an electronic apparatus 2 is loaded at the loading place 11c. For example, according to the immersion tank 10, even in such thinned loading as depicted in FIG. 11B, flows 41 of the refrigerant 40 similar to those in such a full loading state as depicted in FIG. 11A may be implemented in the tank main body 11.

In this manner, according to the immersion tank 10, flows 41 of the refrigerant 40 similar to those upon full loading may be implemented also upon thinned loading, and fluctuation of the flows 41 of the refrigerant 40 flowing around a certain electronic apparatus 2 in the tank main body 11 by the type, quantity and disposition of the other electronic apparatus 2 loaded around the certain electronic apparatus 2 may be suppressed. For example, fluctuation of the flow rate distribution of the refrigerant 40 in the tank main body 11 may be suppressed between thinned loading and full loading. In the immersion tank 10, fluctuation of the flows 41 of the refrigerant 40 flowing around an electronic apparatus 2 disposed at a certain loading place 11c is suppressed. Therefore, influence of the type, quantity and disposition of the other electronic apparatus 2 loaded around the certain electronic apparatus 2 upon the certain electronic apparatus 2 is suppressed, and it is facilitated to grasp the worst conditions upon operation.

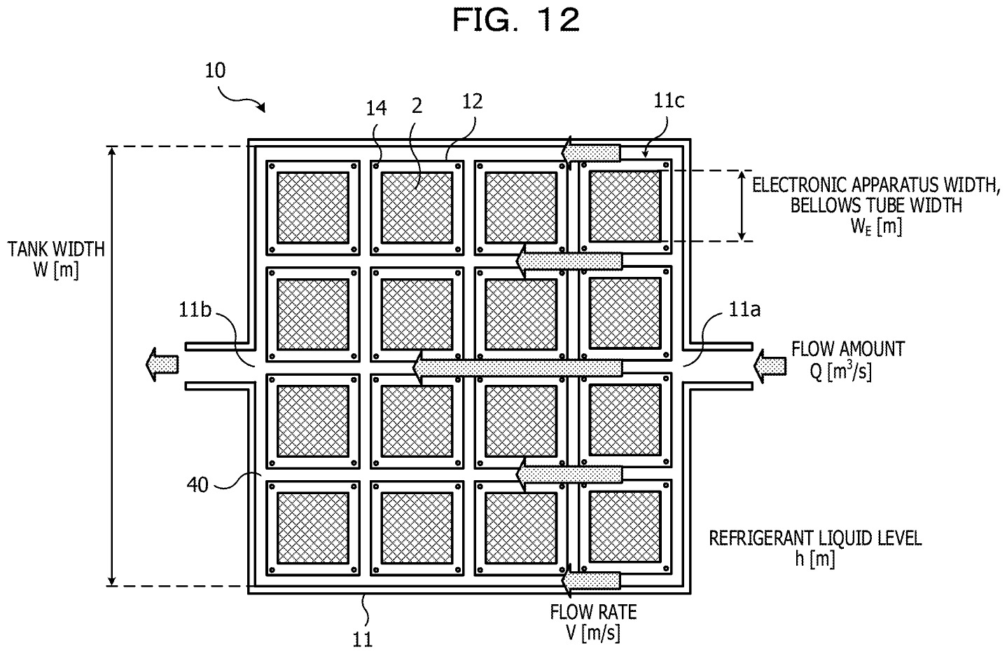

The flow rate of the refrigerant 40 in the tank main body 11 is described with further reference to FIG. 12. FIG. 12 is a view illustrating the flow rate of refrigerant in an immersion tank according to the first embodiment. FIG. 12 schematically depicts a partial plan view of an example of the immersion tank in which electronic apparatus are fully loaded. It is to be noted that FIG. 12 corresponds to a sectional view when the tank main body of the immersion tank is taken along a plane direction at an intermediate height position between the supply port and the discharge port of the tank main body for the refrigerant.

Although FIG. 12 depicts the immersion tank 10 in which electronic apparatus 2 are fully loaded for the convenience of illustration, the flow rate calculation described below is similar also to that in regard to the immersion tank 10 in which electronic apparatus 2 are thinned and loaded. This is because, in the immersion tank 10, a bellows tube 13 in an extended state exists at each of the loading places 11c from which electronic apparatus 2 are thinned out.

Where the flow rate of the refrigerant 40 supplied from the supply port 11a into the tank main body 11 is represented by Q [m³/s], the flow rate of the refrigerant 40 flowing into the tank main body 11 is represented by V [m/s] and the total area of the flow path of the refrigerant 40 is represented by A [m²], they have a relationship represented by the following expression (1) from a continuous formula:

Q=V×A (1)

The sectional area A of the flow path is calculated by multiplying the width W_{E} [m] of the electronic apparatus 2 and the bellows tube 13 (in its extended state) by the number B (four) of the loading places 11c, subtracting the resulting product from the inner width W [m] of the tank main body 11 and multiplying the resulting difference by the liquid level height h [m] of the refrigerant 40, for example, is represented by the following expression (2):

A=(W−W_{E}×4)×h (2)

Since V=Q/A from the expression (1), if the flow rate Q of the refrigerant 40 is fixed the flow speed V of the refrigerant 40 increases as the sectional area A of the flow path decreases. In this example, since the value of the width W_{E}×place number B is fixed even in full loading and in thinned loading of electronic apparatus 2, the flow speed V of the refrigerant 40 (average flow rate in a certain cross section) is fixed irrespective of the loaded number of electronic apparatus 2.

On the other hand, in the case of an immersion tank in which the bellows tube 13 does not extend upwardly different from the immersion tank 10 described above, in thinned loading, the value of the width W_{E}×place number B decreases and the sectional area A of the flow path increases. Accordingly, if the flow rate Q of the refrigerant 40 is fixed the flow speed V of the refrigerant 40 decreases. For example, in the immersion tank 10 described above in which, if an electronic apparatus 2 is unloaded the bellows tube 13 extends upwardly, it is possible to suppress decrease of the flow speed V that is caused by non-loading of an electronic apparatus 2 at a certain flow path sectional position and keep a maximum flow speed V that is obtained in full loading.

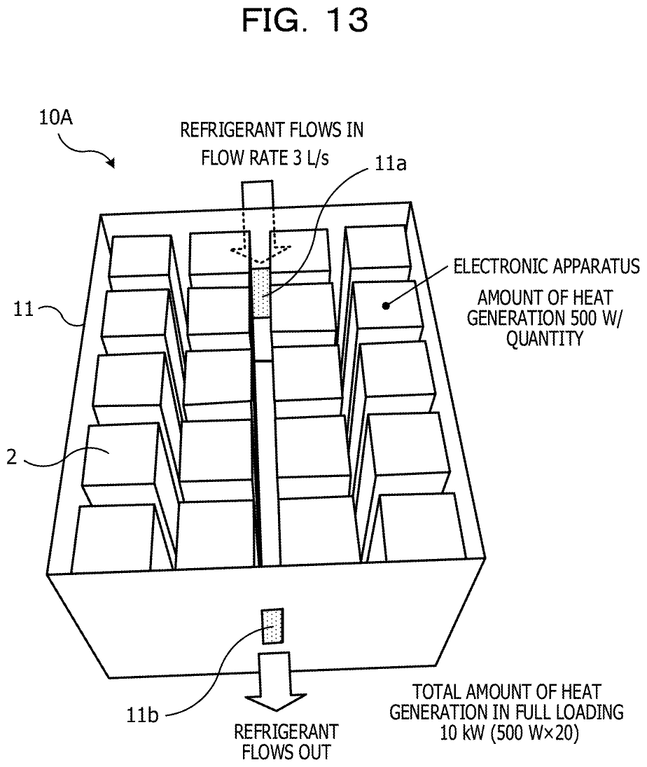

A result of thermal fluid analysis of the immersion tank 10 having such a configuration as described above is described. FIG. 13 is a view depicting a model of the immersion tank used in the thermal fluid analysis.

The model 10A depicted in FIG. 13 is a model that corresponds to one example of such an immersion tank 10 as described above and in which 20 electronic apparatus 2 in the maximum may be loaded as objects to be cooled in the tank main body 11.

In the model 10A, the electronic apparatus 2 to be loaded have an amount of heat generation of 500 W per one electronic apparatus 2. Accordingly, the total amount of heat generation of electronic apparatus 2 in full loading is 10 kW (500 W×20). Into the tank main body 11, refrigerant (fluorinated inert liquid) kept at 10° C. is supplied at a flow rate of 3 L/s (Q=3×10⁻³ cm³/s) from the supply port 11a, flows in the tank main body 11 and is discharged from the discharge port 11b. The size of the tank main body 11 is 0.8 m wide×1 m deep×0.6 m high. The size of the electronic apparatus 2 is 0.15 m long×0.15 m wide×0.5 m high. In the tank main body 11, the refrigerant 40 (not depicted) is stored up to the height of the upper end of the tank main body 11.

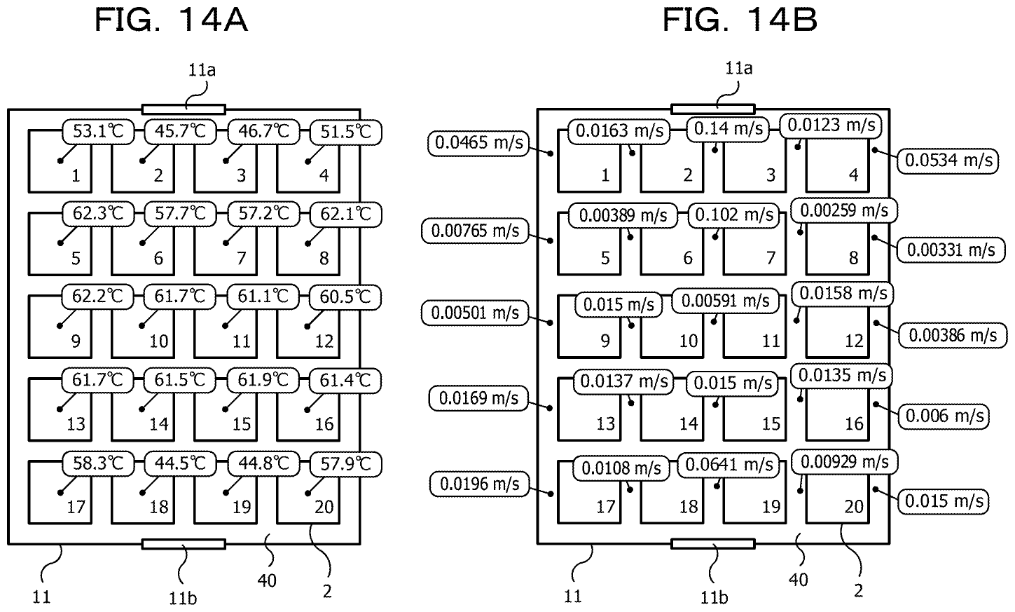

An example of a result of the thermal fluid analysis in which such a model 10A as described above is depicted in FIGS. 14A to 16B. FIGS. 14A and 14B depict an example of the thermal fluid analysis of the immersion tank in full loading. FIG. 14A depicts an example of a temperature distribution of the electronic apparatus in the tank main body, and FIG. 14B depicts an example of a flow rate distribution of refrigerant in the tank main body. It is to be noted that the temperature distribution depicted in FIG. 14A and the flow rate distribution depicted in FIG. 14B are distributions at a cross section where the tank main body is cut in a plane direction at an intermediate height position between the supply port and the discharge port for the refrigerant.

In FIGS. 14A and 14B, the fully loaded electronic apparatus 2 have numbers No. 1 to No. 20 applied thereto. In FIG. 14A, the electronic apparatus 2 loaded in the tank main body 11 indicate a dispersion in temperature depending upon the loading position, and the lowest temperature is 44.5° C. (No. 18) and the highest temperature is 62.3° C. (No. 5). In FIG. 14B, also the flow rate of the refrigerant 40 stored in the tank main body 11 indicates a dispersion. It may be recognized that the flow rate of the refrigerant 40 is highest between the electronic apparatus 2 of No. 2 and No. 3 loaded in the proximity of the supply port 11a and is 0.14 m/s and decreases at the left and right ends. The worst condition to an electronic apparatus 2 is that it is loaded at a location around the electronic apparatus 2 of Nos. 5, 8 and 9 to 16 at which the temperature is higher than 60° C.

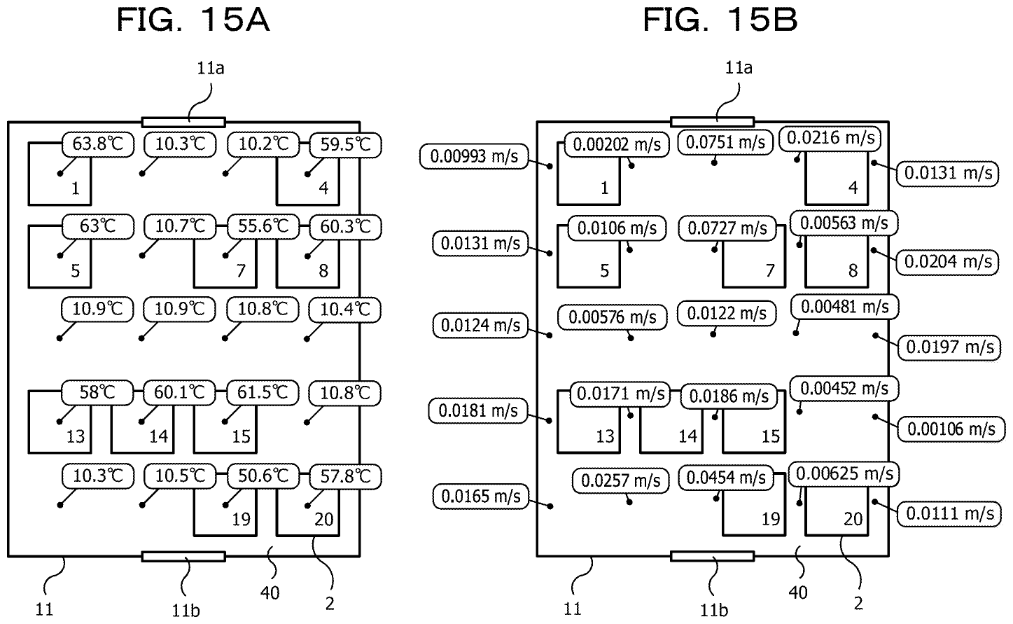

FIGS. 15A and 15B depict an example of a thermal fluid analysis result of the immersion tank in thinned loading which does not include the bellows tube. FIG. 15A depicts an example of a temperature distribution of electronic apparatus in the tank main body, and FIG. 15B depicts an example of a flow velocity distribution of the refrigerant in the tank main body. It is to be noted that the temperature distribution depicted in FIG. 15A and the flow velocity distribution of FIG. 15B are distributions at a cross section where the tank main body is cut in a plane direction at an intermediate height position between the supply port and the discharge port for the refrigerant.

In FIGS. 15A and 15B, the electronic apparatus 2 that are thinned and loaded have numbers Nos. 1, 4, 5, 7, 8, 13 to 15, 19 and 20, which are same as those in full loading, applied thereto. In FIGS. 15A and 15B, the electronic apparatus 2 of Nos. 2, 3, 6, 9 to 12 and 16 to 18 in the case of full loading are thinned out.

In FIG. 15A, the temperature of the electronic apparatus 2 loaded in the tank main body 11 ranges from 50.6° C. (No. 19) to 63.8° C. (No. 1). The temperature at the positions at which the electronic apparatus 2 are thinned out is a temperature around the temperature of the supplied refrigerant 40 (10.2° C. to 10.9° C.). In FIG. 15B, in regard to the flow velocity of the refrigerant 40 stored in the tank main body 11, where it is compared with that in the case of full loading, even if the flow rate of the refrigerant 40 when it is supplied is equal, the flow rate in the tank main body 11 is reduced. This is because, since electronic apparatus 2 are thinned and loaded, the sectional area of the flow path increases and, if the flow rate of the refrigerant 40 supplied is fixed, the flow velocity is reduced as described hereinabove with reference to FIG. 12. Comparing at the same position as upon full loading, the flow speed at the position between the thinned out electronic apparatus 2 of Nos. 2 and 3 decreases significantly to 0.0751 m/s. Although a very great number of combinations are available in thinned loading, in the example of the thinned loading depicted in FIGS. 15A and 15B, a case in which an electronic apparatus 2 is loaded around the electronic apparatus 2 of No. 1 or 5 at which the temperature is higher than 63° C. is the worst condition to the electronic apparatus 2.

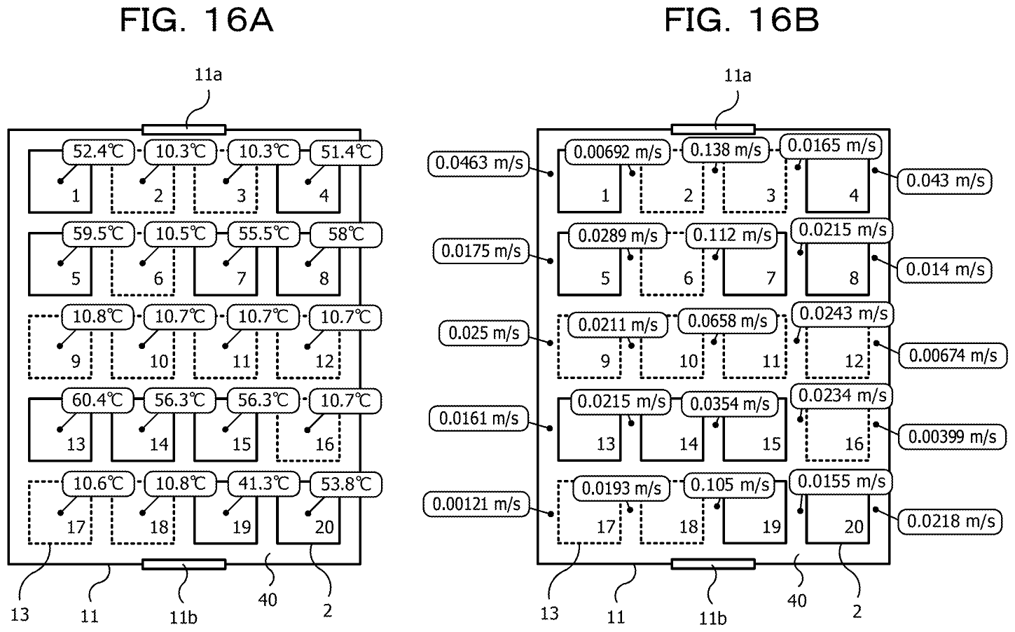

FIGS. 16A and 16B depict an example of a thermal analysis result regarding the immersion tank in thinned loading where the immersion tank includes bellows tubes. FIG. 16A depicts an example of a temperature distribution of electronic apparatus in the tank main body, and FIG. 16B depicts an example of a flow velocity distribution of refrigerant in the tank main body. It is to be noted that the temperature distribution depicted in FIG. 16A and the flow velocity distribution of FIG. 16B are distributions at a cross section where the tank main body is cut in a plane direction at an intermediate height position between the supply port and the discharge port for the refrigerant.

In FIGS. 16A and 16B, the thinned and loaded electronic apparatus 2 have numbers Nos. 1, 4, 5, 7, 8, 13 to 15, 19 and 20 same as those in full loading. In FIGS. 16A and 16B, the electronic apparatus 2 of Nos. 2, 3, 6, 9 to 12 and 16 to 18 in the case of full loading are thinned out. At each of the positions at which the electronic apparatus 2 are thinned out, a bellows tube 13 extended upwardly exists in place of an electronic apparatus 2. In FIGS. 16A and 16B, such bellows tubes 13 that exist extended upwardly in this manner are indicated by broken lines.

In FIG. 16A, the temperature at a position at which a bellows tube 13 exists in an extended form is a temperature around the temperature of the refrigerant 40 supplied (10.3° C. to 10.8° C.) because the bellows tube 13 is not a heat generating element. Although the temperature of the electronic apparatus 2 loaded in the tank main body 11 indicates a distribution similar to that in full loading, since the amount of heat generation around the positions of the bellows tubes 13 decreases to suppress frenzy of heat, there is a tendency that the temperature becomes rather low. In FIG. 16B, also the flow speed of the refrigerant 40 stored in the tank main body 11 indicates a distribution substantially similar to that in full loading. The worst condition to an electronic apparatus 2 is a case in which it is loaded around an electronic apparatus 2 of No. 5, 8 or 13 at which the temperature is around 60° C., and this is similar to that in full loading.

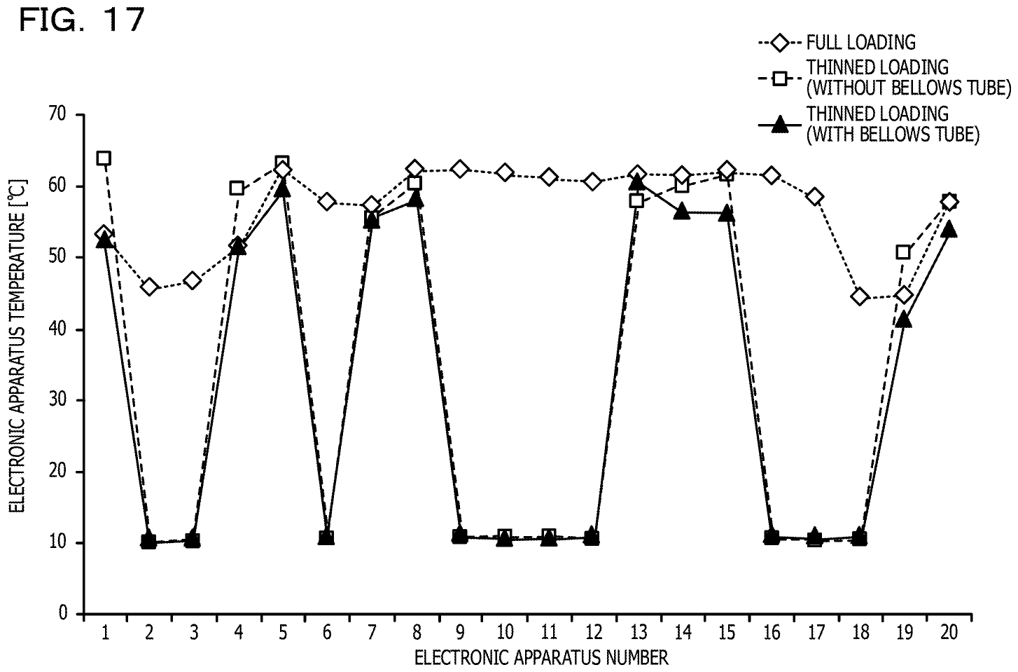

FIG. 17 is a view depicting a result of comparison in electronic apparatus temperature. FIG. 17 is a graph of the temperature of the electronic apparatus 2 of Nos. 1 to 20 obtained by the thermal fluid analysis described hereinabove with reference to FIGS. 14 to 16.

In the immersion tank 10 described hereinabove (in “thinned loading (with bellows tube)” of FIG. 17) in which the bellows tubes 13 exist in an upwardly extended form in place of the thinned out electronic apparatus 2, a tendency may be seen that the temperature of the electronic apparatus 2 loaded without being thinned out is similar to that in full loading (“full loading” of FIG. 17). In contrast, in the immersion tank (“thinned loading (without bellows tube)” of FIG. 17) in which such a bellows tube 13 extending upwardly as described above does not exist at the position of each thinned out electronic apparatus 2, the temperature of an electronic apparatus 2 loaded without being thinned out sometimes becomes, depending upon the loading position of the electronic apparatus 2, higher than that in full loading (“full loading” of FIG. 17).

According to the immersion tank 10, also in thinned loading, cooling similar to that in full loading or cooling that suppresses temperature rise from that in full loading becomes possible, and it becomes possible to sufficiently cool the electronic apparatus 2 loaded in the tank main body 11 using the refrigerant 40. According to the immersion tank 10, if a position of a specific electronic apparatus 2 in the tank main body 11 is determined it becomes possible to roughly grasp to which degree the temperature of the electronic apparatus 2 rises, and therefore, the loading position that is the worst condition to the electronic apparatus 2 in the tank main body 11 may be found out efficiently.

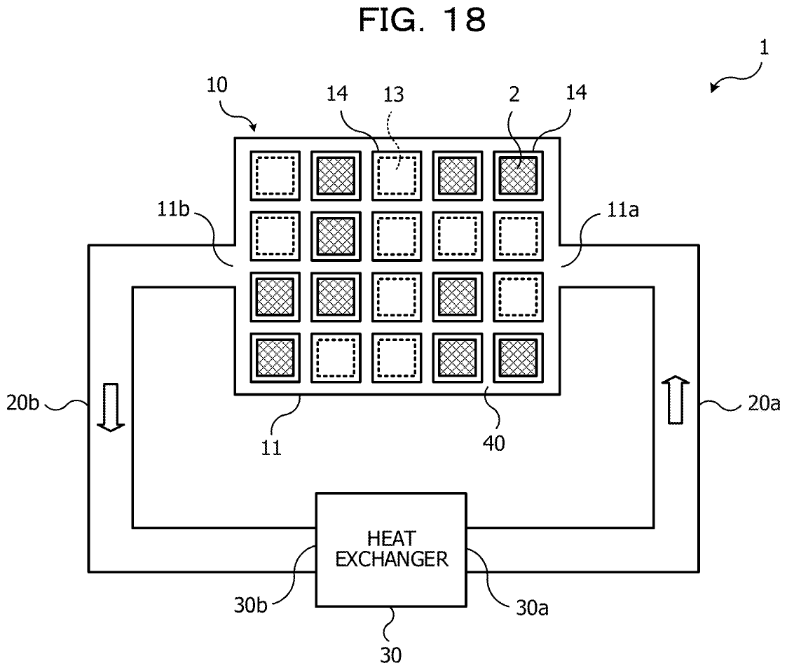

An immersion cooling system that adopts the immersion tank 10 is described. FIG. 18 is a view depicting an example of the immersion cooling system according to the first embodiment. FIG. 18 depicts a block diagram of an example of the immersion cooling system.

The immersion cooling system 1 depicted in FIG. 18 is a system that performs immersion cooling for electronic apparatus 2, for example, electronic apparatus 2 that configure various computer systems such as a supercomputer or a high performance computer.

The immersion cooling system 1 includes such an immersion tank 10 as described above. The immersion tank 10 includes a tank main body 11 on which a supply port 11a and a discharge port 11b for refrigerant 40, and electronic apparatus 2 are immersed in the refrigerant 40 stored in the tank main body 11. FIG. 18 depicts an example in which electronic apparatus 2 are thinned and loaded in the tank main body 11. At each of the loading places 11c in the tank main body 11, a bellows tube 13 having a pedestal 12 provided at an upper end 13b thereof is disposed. At a loading place 11c at which an electronic apparatus 2 is loaded, the electronic apparatus 2 is placed on the pedestal 12 and the bellows tube 13 is contracted downwardly. At a loading place 11c at which an electronic apparatus 2 is not loaded, the bellows tube 13 exists extending upwardly.

To the supply port 11a and the discharge port 11b provided on the tank main body 11, a duct 20a and a duct 20b are coupled, respectively. The duct 20a coupled to the supply port 11a is coupled to an exit 30a of a heat exchanger 30 (cooling apparatus) for the refrigerant 40, and the duct 20b coupled to the discharge port 11b is coupled to an entrance 30b of the heat exchanger 30 for the refrigerant 40.

In the immersion cooling system 1, refrigerant 40 of a comparatively low temperature cooled by the heat exchanger 30 is supplied from the supply port 11a into the tank main body 11 through the duct 20a. The refrigerant 40 supplied into the tank main body 11 from the supply port 11a deprives of heat generated from the electronic apparatus 2 when they operate thereby to cool the electronic apparatus 2. The refrigerant 40 of a comparatively high temperature warmed by depriving of heat generated by the electronic apparatus 2 is discharged to the outside of the tank main body 11 from the discharge port 11b and is sent to the heat exchanger 30 through the duct 20b. The refrigerant 40 of the comparatively high temperature sent to the heat exchanger 30 is cooled by the heat exchanger 30. The refrigerant 40 cooled by the heat exchanger 30 is sent to the tank main body 11 through the duct 20a. In the immersion cooling system 1, the refrigerant 40 is circulated in this manner to perform cooling of the electronic apparatus 2 loaded in the tank main body 11.

In the immersion tank 10, fluctuation of the liquid level of the refrigerant 40 in the tank main body 11 is suppressed by contraction and extension of the bellows tubes 13 each according to loading and unloading of an electronic apparatus 2 at the loading place 11c. In the immersion tank 10, fluctuation of a way of flowing of the refrigerant 40 in the tank main body 11 and fluctuation of a temperature distribution and a flow velocity distribution by the way of flowing are suppressed irrespective of whether or not an electronic apparatus 2 is loaded at each loading place 11c. This implements sufficient cooling of the electronic apparatus 2 loaded in the tank main body 11. By adopting such an immersion tank 10 as described above, the immersion cooling system 1 may be implemented which may sufficiently cool electronic apparatus 2 that configure various computer systems.

It is to be noted that, although the foregoing description is given exemplifying the bellows tube 13, such a bellows tube 13 is not restrictive, and any member may be applied if it contracts and is retracted to the bottom portion 11d of the tank main body 11 when an electronic apparatus 2 is loaded but extends upwardly from the bottom portion 11d of the tank main body 11 when the electronic apparatus 2 is unloaded. For example, such a bellows tube 13 as described above may be replaced by a pipe that extends or contracts in a foldable way or a pop-up way, a bag, a damper or the like.

### Second Embodiment

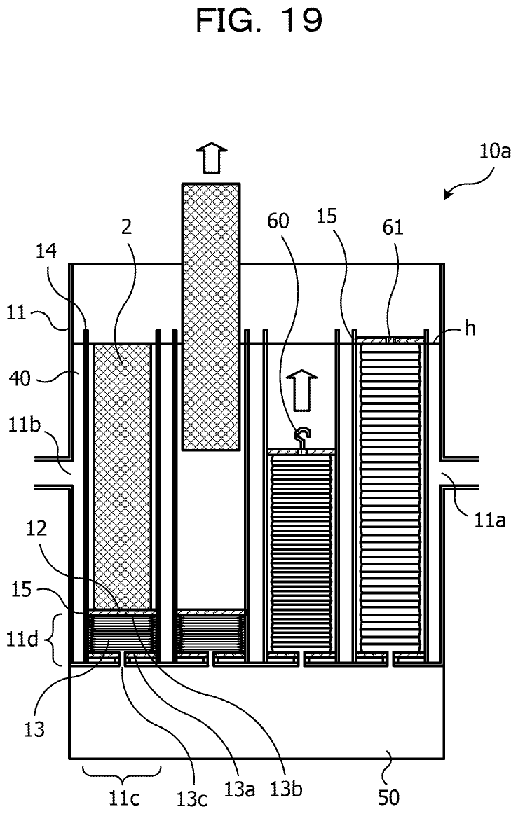

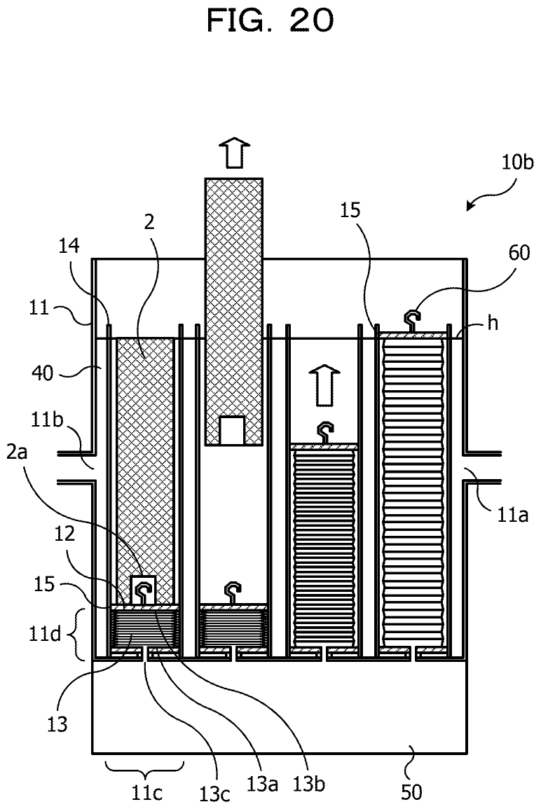

FIGS. 19 and 20 are views depicting an example of an immersion tank according to a second embodiment. Each of FIGS. 19 and 20 schematically depicts a partial sectional view of an example of the immersion tank.

The immersion tank 10a depicted in FIG. 19 is different from the immersion tank 10 described hereinabove in connection with the first embodiment in that a hook 60 is provided on the pedestal 12 of each loading place 11c of the tank main body 11. The hook 60 is screwed to a hook attaching portion 61, for example, a threaded hole, provided in advance on the pedestal 12 and is attached to the pedestal 12. Alternatively, the hook 60 may be provided in such a mechanism as a pop-up mechanism by which, when an electronic apparatus 2 is loaded on the pedestal 12, the hook 60 is accommodated in the inside of the pedestal 12, but when the electronic apparatus 2 is unloaded from the pedestal 12, the hook 60 projects from the pedestal 12.

In the immersion tank 10a, an electronic apparatus 2 is placed on the pedestal 12 and loaded into the tank main body 11 in which refrigerant 40 is stored (first loading place 11c from the left in FIG. 19). If the electronic apparatus 2 is unloaded from the inside of the tank main body 11 (second loading place 11c from the left in FIG. 19) the pedestal 12 is lifted utilizing the hook 60 provided on the pedestal 12 after the unloading of the electronic apparatus 2 (third loading place 11c from the left in FIG. 19). Together with the lifting of the pedestal 12, the bellows tube 13 is extended upwardly and the pedestal 12 is fixed to the guide rails 14 each by the latch unit 15 (fourth loading place 11c from the left in FIG. 19). In the case where the hook 60 is removably mounted, the hook 60 may be removed after the pedestal 12 is lifted (fourth loading place 11c from the left in FIG. 19).

At the loading place 11c of the tank main body 11 from which the electronic apparatus 2 is unloaded, the bellows tube 13 may exist extending upwardly using the hook 60 provided on such a pedestal 12 as just described.

The immersion tank 10b depicted in FIG. 20 is different from the immersion tank 10a depicted in FIG. 19 in that the hook 60 is attached in advance to the pedestal 12. In the immersion tank 10b, as the electronic apparatus 2 to be placed on the pedestal 12, an electronic apparatus 2 is used in which such a space 2a as does not interfere with the hook 60 attached to the pedestal 12 is provided in advance. In the immersion tank 10b, the electronic apparatus 2 is placed on the pedestal 12 such that the hook 60 is accommodated in the space 2a and is loaded into the tank main body 11 in which refrigerant 40 is stored (first loading place 11c from the left in FIG. 20). If the electronic apparatus 2 is unloaded from within the tank main body 11 (second loading place 11c from the left in FIG. 20) the pedestal 12 is lifted using the hook 60 (third loading place 11c from the left in FIG. 20). Together with the lifting of the pedestal 12, the bellows tube 13 is extended upwardly and the pedestal 12 is fixed to the guide rails 14 each by the latch unit 15 (fourth loading place 11c from the left in FIG. 20).

At the loading place 11c of the tank main body 11 from which the electronic apparatus 2 is unloaded, the bellows tube 13 may exist extending upwardly using the hook 60 attached in advance to such a pedestal 12 as described above.

In the case where the bellows tube 13 is extended upwardly using the hook 60 and then the fixation by the latch unit 15 is cancelled and the bellows tube 13 is contracted utilizing the hook 60 as in the case of the immersion tank 10a or 10b, the adjustment unit 50 for adjusting the internal pressure of the bellows tube 13 may be omitted.

### Third Embodiment

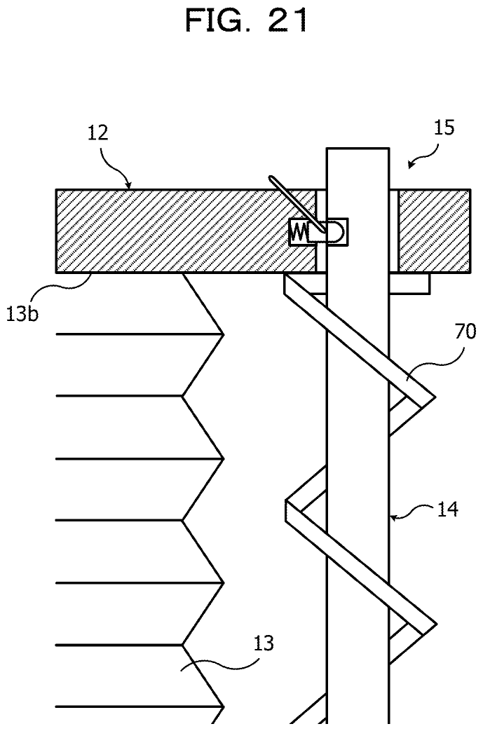

FIG. 21 is a view depicting an example of an immersion tank according to a third embodiment. FIG. 21 schematically depicts a partial sectional view of an example of the immersion tank.

As depicted in FIG. 21, each guide rail 14 that guides a pedestal 12 for upward and downward movement may have a spring 70 provided thereon for biasing the pedestal 12 upwardly. It is to be noted that FIG. 21 depicts a state in which the pedestal 12 is fixed at a lifted position to the guide rail 14 by the latch unit 15. The spring 70 biases the pedestal 12 from the lower end 13a of the bellows tube 13 to the upper end 13b, for example, in the immersion tank 10 (FIG. 4 and so forth) described hereinabove. The spring 70 is provided, for example, in such a manner as to surround the guide rail 14. The spring 70 may not necessarily be provided in such a manner as to surround the guide rail 14 if it biases the pedestal 12 upwardly.

The pedestal 12 is lifted upwardly by the biasing force of the spring 70 or with the aid of the biasing force of the spring 70, and when the pedestal 12 rises, the bellows tube 13 extends upwardly. When the pedestal 12 is pushed downwardly against the biasing force of the spring 70 and the pedestal 12 moves down, the bellows tube 13 contracts downwardly. Upon extension and contraction of the bellows tube 13, the internal pressure of the bellows tube 13 may be adjusted, for example, by the adjustment unit 50 (FIGS. 4, 5, 9 and so forth).

Such a spring 70 as depicted in FIG. 21 may be adopted, for example, in the immersion tank 10 described hereinabove in connection with the first embodiment and besides may be adopted similarly in the immersion tank 10a (FIG. 19) or the immersion tank 10b (FIG. 20) described hereinabove in connection with the second embodiment.

### Fourth Embodiment

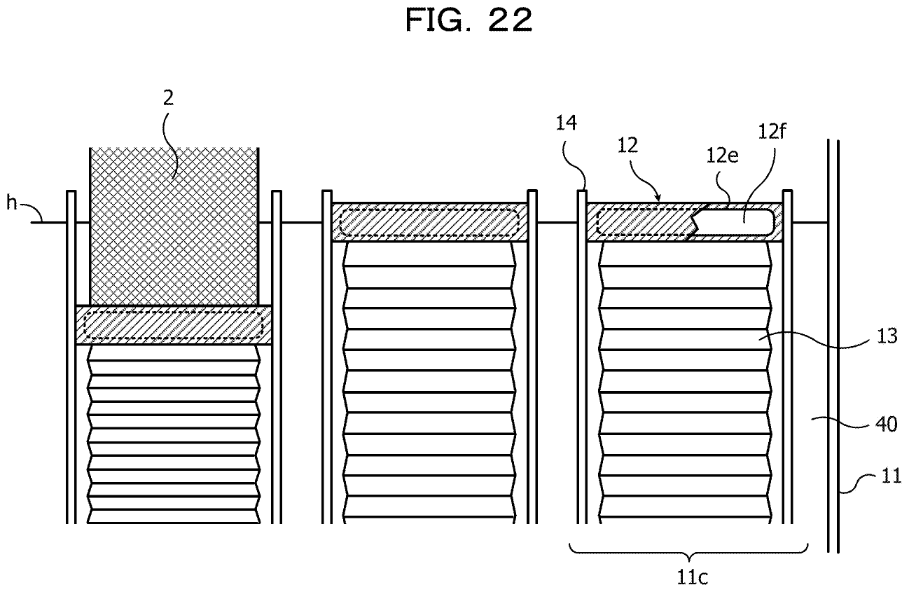

FIG. 22 is a view depicting an example of an immersion tank according to a fourth embodiment. FIG. 22 schematically depicts a partial sectional view of an example of the immersion tank.

As depicted in FIG. 22 (by the rightmost loading place 11c), the pedestal 12 may have a cavity 12e provided in the inside thereof and substance 12f having a specific gravity lower than that of the refrigerant 40 may be filled in the cavity 12e. For the substance 12f to be filled in the cavity 12e of the pedestal 12, gas such as air may be used.

In the refrigerant 40 stored in the tank main body 11, floating power acts on the pedestal 12 having the substance 12f of a low specific gravity filled in the cavity 12e thereof in this manner. In the case where an electronic apparatus 2 is placed on the pedestal 12, the pedestal 12 is pushed down against the floating power, and as the pedestal 12 moves down, the bellows tube 13 contracts downwardly (leftmost loading place 11c in FIG. 22). If the electronic apparatus 2 is unloaded from the pedestal 12 (second loading place 11c from the left in FIG. 22) the pedestal 12 is lifted upwardly by the floating power or with the aid of the floating power, and as the pedestal 12 rises, the bellows tube 13 extends upwardly.

Such a pedestal 12 as depicted in FIG. 22 may be adopted, for example, in the immersion tank 10 described hereinabove in connection with the first embodiment and besides may be adopted similarly in the immersion tank 10a (FIG. 19) or the immersion tank 10b (FIG. 20) described hereinabove in connection with the second embodiment. Such a pedestal 12 as depicted in FIG. 22 may be adopted similarly also in the immersion tanks 10, 10a and 10b that adopt such a spring 70 as described above in connection with the third embodiment.

### Fifth Embodiment

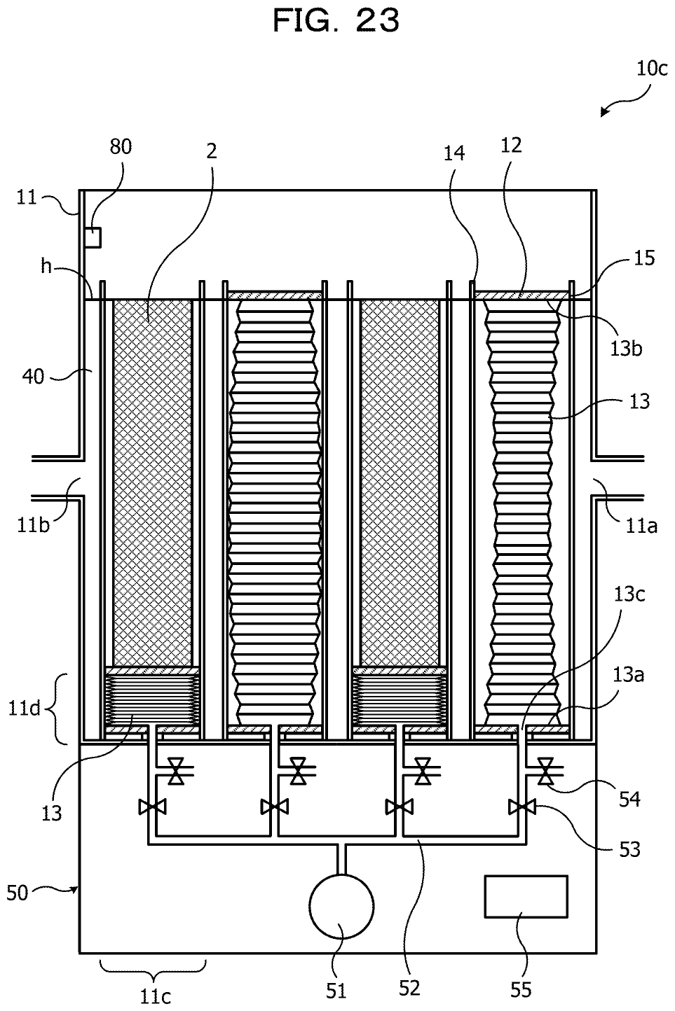

FIG. 23 is a view depicting an example of an immersion tank according to a fifth embodiment. FIG. 23 schematically depicts a partial sectional view of an example of the immersion tank.

For example, in such an immersion tank 10 as described hereinabove in connection with the first embodiment, electronic apparatus 2 of different types are sometimes loaded in the loading places 11c of the tank main body 11. The electronic apparatus 2 of the different types may possibly be different also in volume.

The immersion tank 10c depicted in FIG. 23 is ready for such difference in volume of the electronic apparatus 2. In the immersion tank 10c, each bellows tube 13 is extended and contracted by adjustment of the internal pressure by the adjustment unit 50. Further, in the immersion tank 10c, the extended bellows tube 13 may be fattened or thinned by adjustment (fine adjustment) of the internal pressure by the adjustment unit 50.

For example, at a loading place 11c from which an electronic apparatus 2 having a comparatively great volume is unloaded, the upwardly extended bellows tube 13 is fattened by increase of the internal pressure by the adjustment unit 50 (second loading place 11c from the left in FIG. 23). At another loading place 11c from which an electronic apparatus 2 of a comparatively small volume is unloaded, the upwardly extended bellows tube 13 is thinned by reduction of the internal pressure by the adjustment unit 50 (fourth loading place 11c from the left in FIG. 23).

As an alternative, based on the volume of one, two or more electronic apparatus 2 loaded in the tank main body 11, the liquid level height h (or volume) of the stored refrigerant 40 and a set value for the liquid level height h, the internal pressure of the bellows tube 13 at one, two or more loading places 11c on which an electronic apparatus 2 is not loaded is adjusted to fatten or thin the bellows tube 13. In this case, a sensor 80 for detecting the liquid level height h of the refrigerant 40 stored in the tank main body 11 is provided.

For example, in the immersion tank 10c, the controller 55 of the adjustment unit 50 acquires information of a volume of an electronic apparatus 2 to be unloaded and controls, based on the volume, the opening or closing movement and the opening of the introduction valve 53 and the discharge valve 54 to adjust the internal pressure of the bellows tube 13. By the adjustment of the internal pressure, the extended bellows tube 13 is inflated so as to be fattened or the extended bellows tube 13 is contracted so as to be thinned.

As another alternative, the controller 55 acquires information of the volume of electronic apparatus 2 loaded in the tank main body 11, information of the liquid level height h of the refrigerant 40 detected by the sensor 80 and a set value for the liquid level height h of the refrigerant 40. The controller 55 controls an opening or closing movement and the opening of the introduction valve 53 and the discharge valve 54 such that the detected liquid level height h is made equal to or made close to the set value thereby to adjust the internal pressure of the bellows tube 13. By the adjustment of the internal pressure, the extended bellows tube 13 is inflated so as to be fattened or the extended bellows tube 13 is contracted so as to be thinned.

By adjusting the volume occupied by the upwardly extended bellows tube 13 in the refrigerant 40 in this manner, the liquid level height h of the refrigerant 40 stored in the tank main body 11 may be kept fixed. This makes it possible to sufficiently cover the electronic apparatus 2 in the tank main body 11 with a minimum amount of the refrigerant 40 to implement sufficient cooling of the electronic apparatus 2 with the refrigerant 40 and minimize addition, leakage and pumping up of the refrigerant 40.

The technique described in the description of the fifth embodiment, for example, the technique for adjusting the volume occupied by the upwardly extended bellows tube 13 in the refrigerant 40, may be adopted by the immersion tank 10 described hereinabove in connection with the first embodiment and by the immersion tanks 10a and 10b described hereinabove in connection with the second embodiment. The technique described in connection with the fifth embodiment may be adopted similarly also by the immersion tanks 10, 10a and 10b in which such a spring 70 as described hereinabove in connection with the third embodiment and such a pedestal 12 as described hereinabove in connection with the third embodiment are used.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An immersion tank comprising:
a tank main body in which refrigerant is stored; and
a member that is disposed on the tank main body and retracts, when an electronic apparatus is loaded into the tank main body, to a bottom portion of the tank main body but extends, when the electronic apparatus is unloaded from the tank main body, upwardly from the bottom portion.

2. The immersion tank according to claim 1, wherein
the member extending upwardly from the bottom portion occupies a volume corresponding to the electronic apparatus loaded in the tank main body.

3. The immersion tank according claim 1, wherein
the member is a stretchable member that is fixed at one end of the member to a bottom of the tank main body and is set at the other end of the member a pedestal on which the electronic apparatus is to be placed.

4. The immersion tank according claim 3, further comprising:
a support that is disposed uprightly in an extension and contraction direction of the member on the outer side of the electronic apparatus to be loaded and the member and guides the pedestal for upward and downward movement.

5. The immersion tank according claim 3, further comprising:
an adjuster that adjusts the internal pressure of the member; wherein
the pedestal moves up when the member extends by increase of the internal pressure by the adjuster and moves down when the member contracts by decrease of the internal pressure by the adjuster.

6. The immersion tank according claim 3, wherein
the member further includes a hook or a hook attaching portion disposed on a face of the pedestal on which the electronic apparatus is to be placed.

7. The immersion tank according claim 3, further comprising:
a spring that biases the pedestal from the one end to the other end of the member; wherein
the pedestal moves up with the aid of biasing force of the spring and moves down against the biasing force of the spring.

8. The immersion tank according claim 3, wherein
the pedestal has a specific gravity lower than that of the refrigerant and moves up with the aid of floating power of the pedestal but moves down against the floating power of the pedestal.

9. The immersion tank according claim 3, further comprising:
a controller that controls expansion or contraction of the extended member based on a volume of the electronic apparatus that is to be unloaded from the tank main body.

10. The immersion tank according claim 3, further comprising:
a fixing tool that fixes a position of the pedestal.

11. An immersion cooling system, comprising:
an immersion tank including;
a tank main body in which refrigerant is stored, and
a member that is disposed on the tank main body and retracts, when an electronic apparatus is loaded into the tank main body, to a bottom portion of the tank main body but extends, when the electronic apparatus is unloaded from the tank main body, upwardly from the bottom portion,
a first duct that supplies the refrigerant into the tank main body;
a second duct that discharges the refrigerant out of the tank main body; and
a cooling apparatus that cools the refrigerant discharged from the second duct and sends the cooled refrigerant to the first duct.
